(19) United States
(12) Patent Application Publication
(10) Pub. No.: US 2026/0262215 A1
(43) Pub. Date: Sep. 3, 2026

(54) SEMICONDUCTOR DEVICE AND METHOD FOR MANUFACTURING THE SAME

(71) Applicant: SAMSUNG ELECTRONICS CO., LTD., Suwon-si (KR)

(72) Inventors: Cheol Hyun AN, Suwon-si (KR); Jin Ho LEE, Suwon-si (KR); Won Sik CHOI, Suwon-si (KR); Ji Eun LEE, Suwon-si (KR); Jin-Su LEE, Suwon-si (KR); Jin Wook LEE, Suwon-si (KR); Chang Hwa JUNG, Suwon-si (KR)

(73) Assignee: SAMSUNG ELECTRONICS CO., LTD., Suwon-si (KR)

(21) Appl. No.: 19/379,181

(22) Filed: Nov. 4, 2025

(30) Foreign Application Priority Data
Feb. 28, 2025 (KR) 10-2025-0026686

(51) Int. Cl. H10B 12/00

(52) U.S. Cl. CPC H10B 12/315; H10B 12/033

(57) ABSTRACT

There is provided a semiconductor device having improved electrical characteristics and reliability. The semiconductor device includes an upper electrode, a lower electrode including a first metal element, a lower inserted electrode film disposed between the upper electrode and the lower electrode, a lower interfacial electrode film disposed between the lower inserted electrode film and the upper electrode, and a capacitor dielectric film disposed between the lower interfacial electrode film and the upper electrode. The lower inserted electrode film has a rutile structure and includes an oxide of the lower electrode, the lower interfacial electrode film has a rutile structure and includes a second metal element different from the first metal element and an oxide of the second metal element, and the capacitor dielectric film has a tetragonal crystal system and includes an oxide of a third metal element different from the second metal element.

### CROSS-REFERENCE TO RELATED APPLICATION

This application claims priority from Korean Patent Application No. 10-2025-0026686 filed on Feb. 28, 2025 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a semiconductor device and a method for manufacturing the same, and more particularly, to a semiconductor device using a capacitor as a data storage element and a method for manufacturing the same.

### Description of Related Art

In recent years, as a semiconductor device has large-capacity and becomes highly integrated, a design rule thereof continues to decrease. This trend is applied to DRAM (dynamic random access memory) as one of memory semiconductor devices. In order for the DRAM device to operate, capacitance of a predefined level or greater is required for each cell.

Increase in the capacitance increases an amount of charges stored in a capacitor, thereby improving refresh characteristics of the semiconductor device. The improved refresh characteristics of the semiconductor device may improve a yield of the semiconductor device.

In order to increase the capacitance, a method of using a dielectric film having a high dielectric constant for the capacitor or increasing a contact area between a lower electrode of the capacitor and the dielectric film is being studied.

### SUMMARY

A technical purpose of the present disclosure is to provide a semiconductor device having improved electrical characteristics and reliability.

Another technical purpose of the present disclosure is to provide a method for manufacturing a semiconductor device having improved electrical characteristics and reliability.

The technical purposes of the present disclosure are not limited to the technical purposes mentioned above, and other technical purposes not mentioned may be clearly understood by those skilled in the art from the following description.

However, technical purposes of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor device comprising an upper electrode, a lower electrode including a first metal element, a lower inserted electrode film disposed between the upper electrode and the lower electrode, wherein the lower inserted electrode film has a rutile structure, and includes an oxide of the lower electrode, a lower interfacial electrode film disposed between the lower inserted electrode film and the upper electrode, wherein the lower interfacial electrode film has a rutile structure, and includes second metal element different from the first metal element and an oxide of the second metal element, and a capacitor dielectric film disposed between the lower interfacial electrode film and the upper electrode, wherein the capacitor dielectric film has a tetragonal crystal system, and includes a third metal element different from the second metal element and an oxide of the third metal element.

According to another aspect of the present disclosure, there is provided a semiconductor device comprising a landing pad disposed on a substrate, a lower electrode connected to the landing pad, and extending in one direction, wherein the lower electrode includes a first metal element, a supporter pattern contacting a portion of the lower electrode and including a first surface and a second surface opposite to each other in the one direction, wherein a sidewall of the supporter pattern connects the first surface of the supporter pattern and the second surface of the supporter pattern to each other, and contacts the lower electrode, a lower inserted electrode film contacting the lower electrode and including an oxide of the lower electrode, a lower interfacial electrode film disposed on the lower inserted electrode film and the supporter pattern and contacting the lower inserted electrode film and the supporter pattern, wherein the lower interfacial electrode film extends along the first surface of the supporter pattern and the second surface of the supporter pattern, and includes a second metal element and an oxide of the second metal element, a capacitor dielectric film disposed on the lower interfacial electrode film and contacting the lower interfacial electrode film, wherein the capacitor dielectric film extends along the first surface of the supporter pattern and the second surface of the supporter pattern, and includes a third metal element and an oxide of the third metal element, and an upper electrode disposed on the capacitor dielectric film.

According to another aspect of the present disclosure, there is provided a semiconductor device comprising an upper electrode, a lower electrode including a first metal element or a nitride of the first metal element, a lower inserted electrode film contacting the lower electrode and disposed between the upper electrode and the lower electrode, wherein the lower inserted electrode film includes an oxide of the lower electrode, a lower interfacial electrode film contacting the lower inserted electrode film and disposed between the lower inserted electrode film and the upper electrode, wherein the lower interfacial electrode film has a rutile structure, and includes a second metal element different from the first metal element and an oxide of the second metal element, and a capacitor dielectric film contacting the lower interfacial electrode film and disposed between the lower interfacial electrode film and the upper electrode, wherein the capacitor dielectric film has a tetragonal crystal system, and includes a third metal element different from the second metal element and an oxide of the third metal element, wherein a preferred growth crystal plane of the capacitor dielectric film on the lower electrode is a (110) plane.

According to another aspect of the present disclosure, there is provided a method for manufacturing a semiconductor device, the method comprising forming a pre-lower electrode including a first metal element, oxidizing a portion of the pre-lower electrode to form a lower electrode and a lower inserted electrode film, wherein the lower inserted electrode film includes an oxide of the pre-lower electrode, forming a lower interfacial electrode film on the lower inserted electrode film, wherein the lower interfacial electrode film includes second metal element different from the first metal element and an oxide of the second metal element, and forming a capacitor dielectric film on the lower interfacial electrode film, the capacitor dielectric film including a third metal element different from the second metal element and an oxide of the third metal element.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is an example diagram for illustrating a semiconductor device according to some embodiments.

FIG. 2 is a graph for illustrating metal elements respectively included in a lower electrode, a lower inserted electrode film, a lower interfacial electrode film, and a capacitor dielectric film of FIG. 1.

FIG. 3 illustrates an enlarged view of a portion P in FIG. 1

FIG. 4 is a schematic layout of a semiconductor device according to some embodiments.

FIG. 5 is a layout illustrating only a word line and a cell active area of FIG. 4.

FIG. 6 illustrates an example cross-sectional view taken along a line A-A in FIG. 4.

FIG. 7 illustrates an example cross-sectional view taken along a line B-B in FIG. 4.

FIG. 8 illustrates an enlarged view of a portion Q in FIG. 6.

FIG. 9 illustrates a plan view taken along a line C-C in FIG. 6.

FIGS. 10 and 11 illustrate enlarged views of portions R1 and R2 in FIG. 9.

FIG. 12 is a diagram for illustrating a semiconductor device according to some embodiments.

FIG. 13 is a layout diagram for illustrating a semiconductor device according to some embodiments.

FIG. 14 illustrates a perspective view of the semiconductor device in FIG. 13.

FIG. 15 illustrates a cross-sectional view taken along lines D-D and E-E of FIG. 13.

FIG. 16 illustrates an enlarged view of a portion S in FIG. 15.

FIG. 17 is a diagram for illustrating a semiconductor device according to some embodiments.

FIG. 18 is a layout diagram for illustrating a semiconductor device according to some embodiments.

FIG. 19 illustrates a perspective view of the semiconductor device in FIG. 18.

FIG. 20 is a diagram for illustrating a semiconductor device according to some embodiments.

FIGS. 21, 22, 23, and 24 are diagrams of intermediate structures corresponding to intermediate steps of a method for manufacturing a semiconductor device according to some embodiments.

FIGS. 25, 26, 27, 28, and 29 are diagrams of intermediate structures corresponding to intermediate steps of a method for manufacturing a semiconductor device according to some embodiments.

### DETAILED DESCRIPTIONS

It will be understood that, although the terms "first", "second", "third", and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

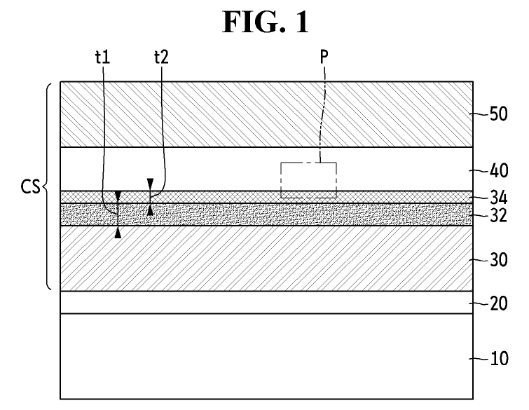

Referring to FIGS. 1 to 3, a semiconductor device according to some embodiments will be described.

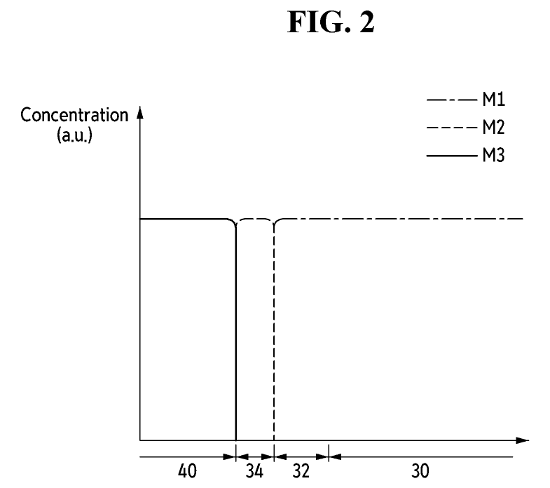

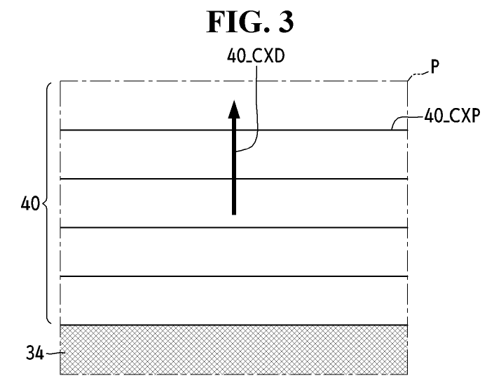

FIG. 1 is an example diagram for illustrating a semiconductor device according to some embodiments. FIG. 2 is a graph for illustrating metal elements respectively included in a lower electrode, a lower inserted electrode film, a lower interfacial electrode film, and a capacitor dielectric film of FIG. 1. FIG. 3 is an enlarged view of a portion P of FIG. 1.

For reference, FIG. 3 may be a diagram for illustrating a crystal plane and a crystal growth orientation of one of crystal grains included in the capacitor dielectric film.

Referring to FIGS. 1 to 3, the semiconductor device according to some embodiments may include a capacitor structure CS.

The capacitor structure CS may be disposed on a first substrate 10 and a lower insulating film 20.

The first substrate 10 may be made of bulk silicon or (SOI) silicon-on-insulator. Alternatively, the first substrate 10 may be embodied as a silicon substrate, or may include a material other than silicon, such as silicon germanium, SGOI (silicon germanium on insulator), indium antimonide, a lead telluride compound, indium arsenide, indium phosphide, gallium arsenide or gallium antimonide. However, embodiments of the present disclosure are not limited thereto.

The lower insulating film 20 may be disposed on the first substrate 10. The lower insulating film 20 may include, for example, at least one of silicon oxide, silicon nitride, silicon oxynitride, and a low dielectric constant (low-k) material having a dielectric constant lower than that of silicon oxide. The low-k material may include, but is not limited to, at least one of FOX (Flowable Oxide), TOSZ (Tonene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, or combinations thereof.

The capacitor structure CS may be disposed on the first substrate 10. The capacitor structure CS may include a lower electrode 30, a lower inserted electrode film 32, a lower interfacial electrode film 34, a capacitor dielectric film 40, and an upper electrode 50.

The lower inserted electrode film 32, the lower interfacial electrode film 34, and the capacitor dielectric film 40 are disposed between the lower electrode 30 and the upper electrode 50. The lower inserted electrode film 32 and the lower interfacial electrode film 34 are disposed between the lower electrode 30 and the capacitor dielectric film 40. The lower interfacial electrode film 34 is disposed between the lower inserted electrode film 32 and the capacitor dielectric film 40. The capacitor structure CS may store charges in the capacitor dielectric film 40 using a potential difference generated between the lower electrode 30 and the upper electrode 50.

The lower electrode 30 may include a first metal element M1. The lower electrode 30 may include a metal film made of the first metal element M1 or a metal nitride film made of a nitride of the first metal element M1.

The first metal element M1 may include, for example, one of cobalt (Co), copper (Cu), molybdenum (Mo), niobium (Nb), titanium (Ti), tantalum (Ta), or vanadium (V). However, embodiments of the present disclosure are not limited thereto.

The lower inserted electrode film 32 may be disposed on the lower electrode 30. The lower inserted electrode film 32 may be disposed between the lower electrode 30 and the lower interfacial electrode film 34. The lower inserted electrode film 32 is in contact with the lower electrode 30.

The lower inserted electrode film 32 may include an oxide of the lower electrode 30. The lower inserted electrode film 32 may include an oxide of the first metal element M1 or an oxynitride of the first metal element M1. For example, the lower inserted electrode film 32 may be formed by oxidizing the lower electrode 30.

The lower inserted electrode film 32 may induce a crystalline phase of the capacitor dielectric film 40. For example, the lower inserted electrode film 32 may have a rutile structure. The first metal element M1 included in the lower electrode 30 may be a metal selected such that an oxide of the first metal element M1 or an oxynitride of the first metal element M1 can induce a crystalline phase of the capacitor dielectric film 40. In other words, the oxide of the first metal element M1 or the oxynitride of the first metal element M1 may have a rutile structure.

In one example, the lower inserted electrode film 32 may include an oxide of the first metal element M1 having a rutile structure. In another example, the lower inserted electrode film 32 may include oxynitride of the first metal element M1 having a rutile structure.

The lower interfacial electrode film 34 may be disposed on the lower inserted electrode film 32. The lower interfacial electrode film 34 may contact the lower inserted electrode film 32.

The lower interfacial electrode film 34 may include a second metal element M2 different from the first metal element M1 included in the lower electrode 30. In one embodiment, the lower interfacial electrode film 34 may further include an oxide of the second metal element M2. The second metal element M2 may include, for example, one of cobalt (Co), molybdenum (Mo), niobium (Nb), tin (Sn), tantalum (Ta), titanium (Ti), or vanadium (V). However, embodiments of the present disclosure are not limited thereto.

The lower interfacial electrode film 34 may induce a crystalline phase of the capacitor dielectric film 40. In one embodiment, the lower interfacial electrode film 34 may have a rutile structure. The oxide of the second metal element M2 may have a rutile structure. The lower interfacial electrode film 34 may include an oxide of the second metal element M2 having a rutile structure.

In some cases, the lower interfacial electrode film 34 may include a first dopant element. The first dopant element included in the lower interfacial electrode film 34 may be different from the second metal element M2. The lower interfacial electrode film 34 may include an oxide of the second metal element M2 doped with the first dopant element.

In one embodiment, the first dopant element may include at least one of niobium (Nb), tin (Sn), or tantalum (Ta). The lower interfacial electrode film 33 may include a first dopant element of 5 at.% (atomic percent) or smaller.

When a content of the first dopant element exceeds 5 at.% (atomic percent), the crystallinity of the lower interfacial electrode film 34 may be poor. In other words, the rutile structure of the lower interfacial electrode film 34 may be broken in at least a portion of the lower interfacial electrode film 34.

In one embodiment, a thickness t1 of the lower inserted electrode film 32 may be greater than or equal to a thickness t2 of the lower interfacial electrode film 34. When the thickness t2 of the lower interfacial electrode film 34 is greater than the thickness t1 of the lower inserted electrode film 32, the crystallinity of the capacitor dielectric film 40 may be not induced.

The capacitor dielectric film 40 may be disposed on the lower interfacial electrode film 34. The capacitor dielectric film 40 is disposed between the lower interfacial electrode film 34 and the upper electrode 50. The capacitor dielectric film 40 may be in contact with the lower interfacial electrode film 34.

The capacitor dielectric film 40 may include a third metal element M3 different from the second metal element M2 included in the lower interfacial electrode film 34. In one embodiment, the capacitor dielectric film 40 may include an oxide of the third metal element M3.

The capacitor dielectric film 40 may include an oxide of the crystalline third metal element M3. The capacitor dielectric film 40 may include a crystalline metal oxide. For example, the capacitor dielectric film 40 may have a tetragonal crystal system. The capacitor dielectric film 40 may include an oxide of the third metal element M3 having a tetragonal crystal system.

The third metal element M3 may include, for example, at least one of zirconium (Zr), hafnium (Hf), titanium (Ti), or strontium (Sr). In one embodiment, the capacitor dielectric film 40 may include one of zirconium oxide, hafnium oxide, titanium oxide, or strontium-titanium oxide. However, embodiments of the present disclosure are not limited thereto. The oxide of the third metal element M3 may have a tetragonal crystal system.

In one example, the capacitor dielectric film 40 may have a rutile structure included in the tetragonal crystal system. The capacitor dielectric film 40 may include an oxide of the third metal element M3 having a rutile structure.

In FIGS. 1 and 3, the capacitor dielectric film 40 may include a crystal plane 40_CXP grown in a crystal orientation 40_CXD. The capacitor dielectric film 40 may include at least one crystal grain. Each crystal grain included in the capacitor dielectric film 40 may include the crystal plane 40_CXP grown in the crystal orientation 40_CXD.

The crystal plane 40_CXP of the capacitor dielectric film may be a crystal plane of the capacitor dielectric film 40. The crystal orientation 40_CXD of the capacitor dielectric film may be an orientation in which a preferred growth crystal plane of the capacitor dielectric film 40 is grown. For example, on the lower electrode 30, the preferred growth crystal plane of the capacitor dielectric film 40 may be the (110) plane. In other words, the orientation in which the capacitor dielectric film 40 is preferentially grown on the lower electrode 30 may be the orientation.

Each crystal grain included in the capacitor dielectric film 40 may include crystal planes. In the semiconductor device according to some embodiments, each crystal grain included in the capacitor dielectric film 40 may include the (110) plane grown in the orientation as the preferred growth orientation. In other words, the capacitor dielectric film 40 may include crystal grains including oxide crystals of the third metal element M3 grown in the orientation.

In some cases, the capacitor dielectric film 40 may include a second dopant element. The second dopant element included in the capacitor dielectric film 40 may be different from the third metal element M3. The capacitor dielectric film 40 may include an oxide of the third metal element M3 doped with the second dopant element.

In one embodiment, the second dopant element may include at least one of aluminum (Al), barium (Ba), beryllium (Be), germanium (Ge), magnesium (Mg), niobium (Nb), silicon (Si), tantalum (Ta), or yttrium (Y). However, embodiments of the present disclosure are not limited thereto.

The capacitor dielectric film 40 is illustrated as a single film. However, embodiments of the present disclosure are not limited thereto.

The upper electrode 50 may be disposed on the capacitor dielectric film 40. The upper electrode 50 may include a conductive material. For example, the upper electrode 50 may include a doped semiconductor material, a conductive metal nitride (e.g., titanium nitride, tantalum nitride, niobium nitride, molybdenum nitride, tungsten nitride, etc.), a metal (e.g., ruthenium, iridium, titanium, niobium, nickel, copper, molybdenum, or tantalum, etc.), a conductive metal oxide (e.g., iridium oxide, molybdenum oxide, etc.), etc. However, embodiments of the present disclosure are not limited thereto.

Since the lower inserted electrode film 32 and the lower interfacial electrode film 34 having a rutile structure are disposed between the lower electrode 30 and the capacitor dielectric film 40, the capacitor dielectric film 40 may include crystal grains having a tetragonal crystal system. The metal oxide included in the capacitor dielectric film 40 may have various structures. However, since the lower inserted electrode film 32 and the lower interfacial electrode film 34 having the rutile structure induce the crystallinity and the crystal structure of the capacitor dielectric film 40, the capacitor dielectric film 40 may have a crystallinity and a crystal structure having a higher dielectric constant. Accordingly, the performance and reliability of the semiconductor device may be improved.

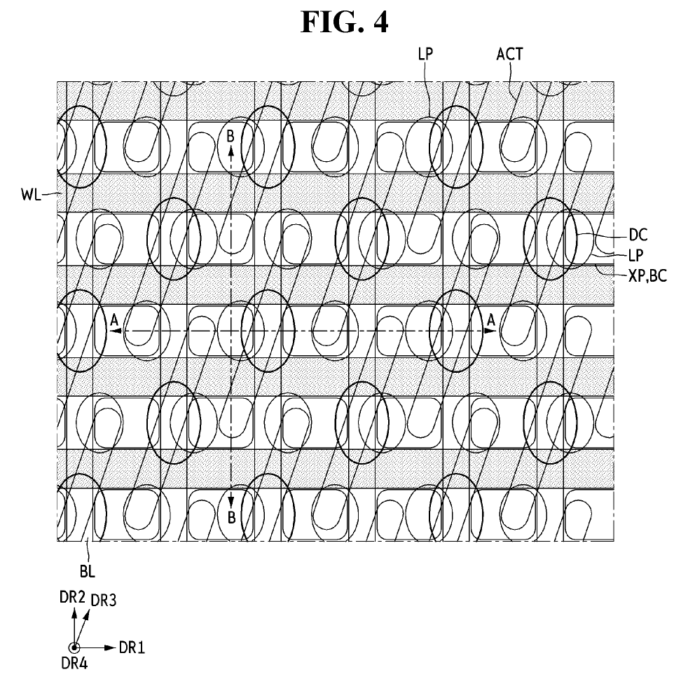

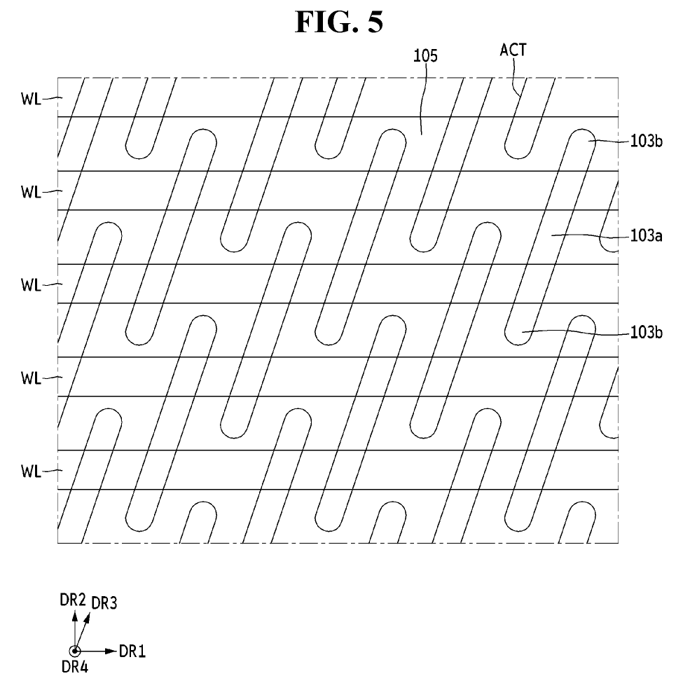

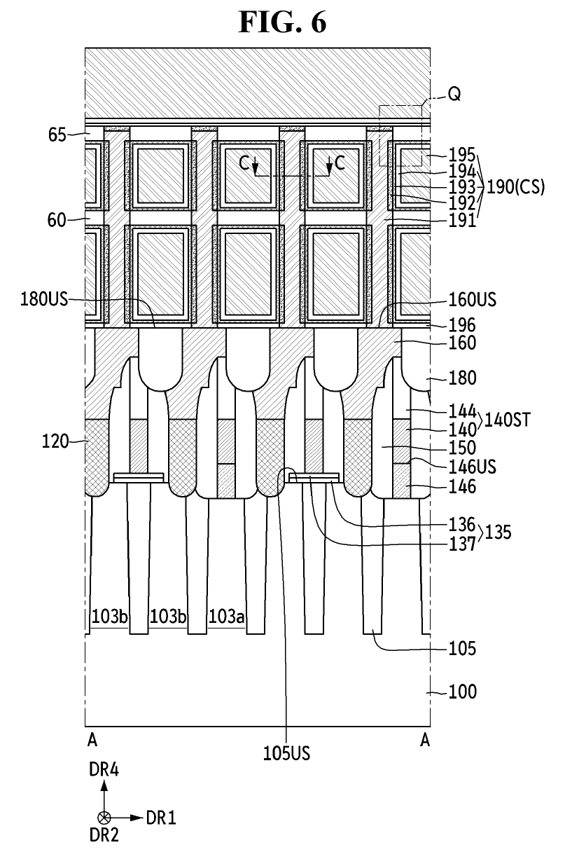

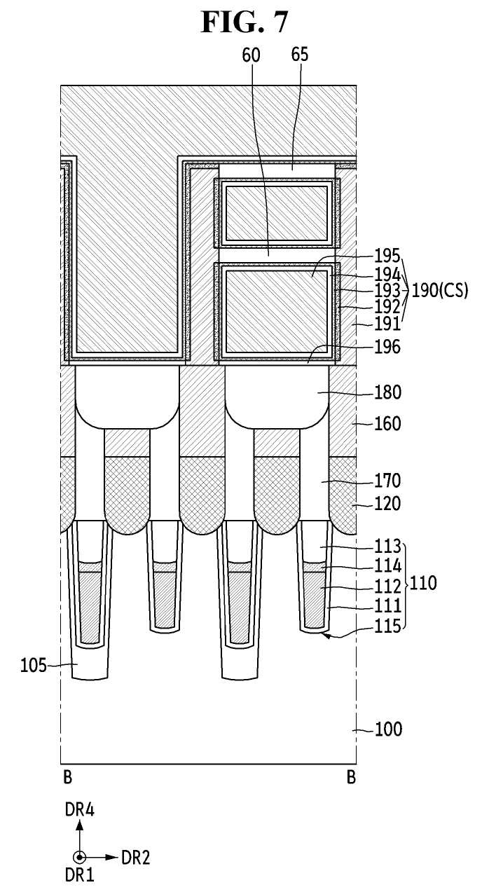

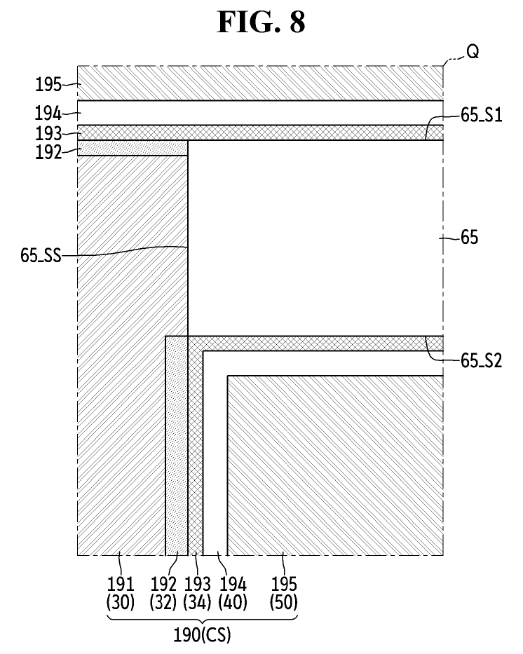

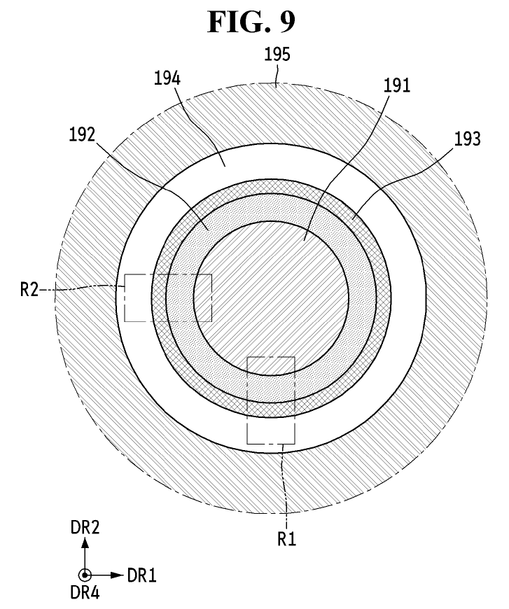

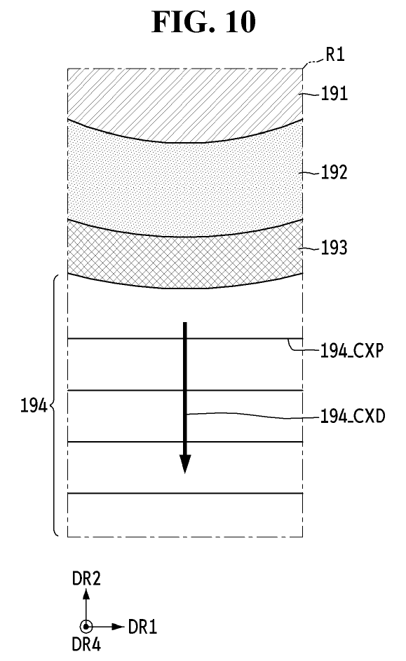

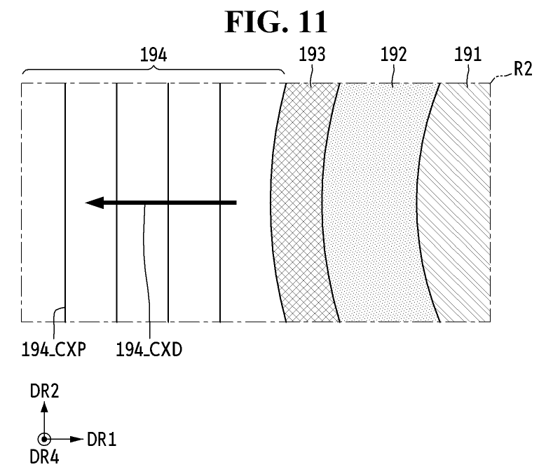

FIG. 4 is a schematic layout of a semiconductor device according to some embodiments. FIG. 5 is a layout illustrating only a word line and a cell active area of FIG. 4. FIG. 6 is an example cross-sectional view taken along a line A-A of FIG. 4. FIG. 7 is an example cross-sectional view taken along a line B-B of FIG. 4. FIG. 8 is an enlarged view of a portion Q of FIG. 6. FIG. 9 is a plan view taken along a line C-C of FIG. 6. FIGS. 10 and 11 are enlarged views of portions R1 and R2 of FIG. 9. For convenience of description, contents duplicate with those as described above with reference to FIGS. 1 to 3 will be briefly described or the descriptions thereof will be omitted.

For reference, FIGS. 10 and 11 may be diagrams for illustrating a crystal plane and a crystal growth orientation of one of crystal grains included in the first capacitor dielectric film.

In the drawings of the semiconductor device according to some embodiments, a dynamic random access memory (DRAM) is illustrated by way of example. However, embodiments of the present disclosure are not limited thereto.

Referring to FIGS. 4 and 5, the semiconductor device according to some embodiments may include a plurality of cell active areas ACT.

The cell active area ACT may be defined by a cell element isolation film 105 formed in a second substrate 100 (see FIG. 6). According to a decrease in the design rule of the semiconductor device, the cell active area ACT may be disposed in a form of a bar of a diagonal line or an oblique line as shown in the drawing. For example, the cell active area ACT may extend in a third direction DR3.

A plurality of gate electrodes GE extending in the first direction DR1 across the cell active area ACT may be disposed. The plurality of gate electrodes GE may extend in parallel to each other. The plurality of gate electrodes GE may be, for example, a plurality of word lines WL (e.g., cell gate electrodes 112 in FIG. 7). The word lines WL may be arranged so as to be spaced from each other by an equal spacing. A width of the word line WL or the spacing between the word lines WL may be determined according to a design rule.

Each cell active area ACT may be divided into three portions by two word lines WL extending in the first direction DR1. The cell active area ACT may include a storage connection area 103b and a bit line connection area 103a. The bit line connection area 103a may constitute a middle portion of the cell active area ACT, and the storage connection areas 103b may respectively constitute both opposing end portions of the cell active area ACT.

For example, the bit line connection area 103a may be an area connected to a bit line BL (e.g., a cell conductive line 140 in FIG. 6), and the storage connection area 103b may be an area connected to a first capacitor structure 190 (see FIG. 6). In other words, the bit line connection area 103a may correspond to a common drain area, and the storage connection area 103b may correspond to a source area. Each word line WL, the bit line connection area 103a, and the storage connection areas 103b adjacent thereto may constitute a transistor.

A plurality of bit lines BL extending in the second direction DR2 orthogonal to the word line WL may be disposed on the word line WL. The plurality of bit lines BL may extend in parallel to each other. The bit lines BL may be arranged so as to be spaced from each other by an equal spacing. A width of the bit line BL or the spacing between the bit lines BL may be determined according to a design rule.

A fourth direction DR4 may be perpendicular to the first direction DR1, the second direction DR2, and the third direction DR3. The fourth direction DR4 may be a thickness direction of the substrate 100.

The semiconductor memory device according to some embodiments may include various contact arrangements formed on the cell active area ACT. The various contact arrangements may include, for example, a Direct Contact (DC), a Buried Contact (BC), and a Landing Pad (LP).

In this regard, the direct contact DC may refer to a contact that electrically connects the cell active area ACT to the bit line BL. The buried contact BC may be a contact pad connecting the cell active area ACT to a lower electrode 191 (see FIG. 6) of the first capacitor structure. Due to the arrangement structure, a contact area between the buried contact BC and the cell active area ACT may be small. Accordingly, a conductive landing pad LP may be introduced to increase a contact area between the active area ACT and the buried contact BC, and to increase a contact area between the buried contact BC and the lower electrode 191 of the first capacitor structure.

In the semiconductor device according to some embodiments, the landing pad LP (e.g., storage pads 160 in FIG. 6) may be disposed between the buried contact BC and the lower electrode 191 of the first capacitor structure. Increasing the contact area via the introduction of the landing pad LP may allow a contact resistance between the cell active area ACT and the lower electrode 191 of the first capacitor structure to be reduced.

The direct contact DC may be connected to the bit line connection area 103a. The buried contact BC may be connected to the storage connection area 103b.

As the buried contact BC is disposed at each of both opposing ends of the active area ACT, the landing pad LP may be disposed adjacent to each of both opposing ends of the active area ACT and may partially overlap the buried contact BC. In other words, the buried contact BC may be formed to overlap the cell active area ACT and the cell element isolation film 105 (see FIG. 6) between adjacent word lines WL and between adjacent bit lines BL.

The word line WL may be formed so as to be buried in the second substrate 100 of FIG. 6. The word line WL may extend across the cell active area ACT while being disposed between the direct contacts DC or the buried contacts BC. As illustrated, two word lines WL may intersect one cell active area ACT. As the cell active area ACT extends along the third direction DR3, the word line WL may have an angle smaller than 90 degrees with respective to the extension direction of the active area ACT.

The direct contacts DC may be arranged in a symmetrical manner. The buried contacts BC may be arranged in a symmetrical manner. Accordingly, the direct contacts DC may be arranged in a straight line along each of the first direction DR1 and the second direction DR2. The buried contacts BC may be arranged in a straight line along each of the first direction DR1 and the second direction DR2. Unlike the direct contact DC and the buried contact BC, the landing pads LP may be arranged in a zigzag manner in the second direction DR2 which the bit line BL extends. Further, the landing pads LP arranged in the same line in the second direction DR2 may respectively overlap portions of the same side surface of both opposing side surfaces of the bit-line BL in the first direction DR1.

For example, each of the landing pads LP arranged in a first line in the second direction may partially overlap the left side surface of a corresponding bit line BL, while each of the landing pads LP arranged in a second line in the second direction may partially overlap a right side surface of the corresponding bit line BL.

Referring to FIGS. 4 to 11, the semiconductor device according to some embodiments may include a plurality of cell gate structures 110, a plurality of bit line structures 140ST, a plurality of storage contacts 120, a plurality of bit line contacts 146, and the first capacitor structure 190.

The second substrate 100 may be made of a silicon substrate or a silicon-on-insulator (SOI). Alternatively, the second substrate 100 may include silicon germanium, silicon germanium on insulator (SGOI), indium antimonide, a lead telluride compound, indium arsenide, indium phosphide, gallium arsenide, or gallium antimonide. However, embodiments of the present disclosure are not limited thereto.

The cell element isolation film 105 may be formed in the second substrate 100. The cell element isolation film 105 may have a shallow trench isolation (STI) structure having excellent element isolation ability. The cell element isolation film 105 may define the cell active area ACT in the memory cell area.

The cell active area ACT defined by the cell element isolation film 105 may have an elongate island shape including a short side and a long side, as illustrated in FIGS. 4 and 5. The cell active area ACT may have an oblique shape to have an angle of 90 degrees or smaller with respect to the word line WL formed in the cell element isolation film 105. In addition, the cell active area ACT may have an oblique shape to have an angle of 90 degrees or smaller with respect to the bit line BL formed on the cell element isolation film 105.

The cell element isolation film 105 may include, for example, at least one of a silicon oxide film, a silicon nitride film, and a silicon oxynitride film. However, embodiments of the present disclosure are not limited thereto.

Although the cell element isolation film 105 is illustrated as being embodied as a single insulating film, this is only intended for convenience of illustration, and embodiments of the present disclosure are not limited thereto. The cell element isolation film 105 may include one insulating film or a plurality of insulating films, depending on a distance between the adjacent cell active areas ACT.

Although an upper surface 105US of the cell element isolation film ST and an upper surface of the second substrate 100 are illustrated as being coplanar with each other, this is only intended for convenience of illustration, and embodiments of the present disclosure are not limited thereto.

The cell gate structure 110 may be disposed in the second substrate 100 and the cell element isolation film 105. The cell gate structure 110 may extend across the cell element isolation film 105 and the cell active area ACT defined by the cell element isolation film 105.

The cell gate structure 110 may include a cell gate trench 115, a cell gate insulating film 111, a cell gate electrode 112, a cell gate capping pattern 113, and a cell gate capping conductive film 114.

In this regard, the cell gate electrode 112 may correspond to the word line WL. For example, the cell gate electrode 112 may be the word line WL of FIG. 4. Unlike the illustrated example, the cell gate structure 110 may not include the cell gate capping conductive film 114.

Although not shown, the cell gate trench 115 may be relatively deep in the cell element isolation film 105 and relatively shallow in the cell active areas ACT. A bottom surface of the word line WL may be curved. That is, the depth of the cell gate trench 115 in the cell element isolation film 105 may be greater than the depth of the cell gate trench 115 in the cell active area ACT.

The cell gate insulating film 111 may extend along a sidewall and a bottom surface of the cell gate trench 115. The cell gate insulating film 111 may extend along a profile of at least a portion of the cell gate trench 115.

The cell gate insulating film 111 may include, for example, at least one of silicon oxide, silicon nitride, silicon oxynitride, or a high dielectric constant material having a higher dielectric constant than that of silicon oxide. The high dielectric constant material may include, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or combinations thereof.

The cell gate electrode 112 may be disposed on the cell gate insulating film 111. The cell gate electrode 112 may fill a portion of the cell gate trench 115. The cell gate capping conductive film 114 may extend along an upper surface of the cell gate electrode 112.

The cell gate electrode 112 may include at least one of a metal, a conductive metal nitride, a conductive metal carbonitride, a conductive metal carbide, a conductive metal silicide, a doped semiconductor material, a conductive metal oxynitride, and a conductive metal oxide. The cell gate electrode 112 may include, for example, TiN, TaC, TaN, TiSiN, TaSiN, TaTiN, TiAlN, TaAlN, WN, Ru, TiAl, TiAlC-N, TiAlC, TiC, TaCN, W, Al, Cu, Co, Ti, Ta, Ni, Pt, Ni-Pt, Nb, NbN, NbC, Mo, MoN, MoC, WC, Rh, Pd, Ir, Ag, Au, Zn, V, RuTiN, TiSi, TaSi, NiSi, CoSi, IrO, RuO, or a combination thereof. However, embodiments of the present disclosure are not limited thereto.

The cell gate capping conductive film 114 may include, for example, one of polysilicon, polysilicon-germanium, amorphous silicon, or amorphous silicon-germanium. However, embodiments of the present disclosure are not limited thereto.

The cell gate capping pattern 113 may be disposed on the cell gate electrode 112 and the cell gate capping conductive film 114. The cell gate capping pattern 113 may fill the remaining portion of the cell gate trench 115 after the cell gate electrode 112 and the cell gate capping conductive film 114 have been formed therein. Although the cell gate insulating film 111 is illustrated as extending along a sidewall of the cell gate capping pattern 113, embodiments of the present disclosure are not limited thereto.

The cell gate capping pattern 113 may include, for example, at least one of silicon nitride, silicon oxynitride, silicon oxide, silicon carbonitride, or silicon oxycarbonitride.

An upper surface 113US of the cell gate capping pattern CGP is illustrated as being coplanar with an upper surface 105US of the cell element isolation film ST. However, embodiments of the present disclosure are not limited thereto.

Although not shown, an impurity-doped area may be formed on at least one side of the cell gate structure 110. The impurity-doped area may be a source/drain area of the transistor. The impurity-doped area may be formed in each of the storage connection area 103b and the bit line connection area 103a of FIG. 5.

In FIG. 5, when a transistor including each word line WL, and the bit line connection area 103a and the storage connection area 103b adjacent thereto is an NMOS, each of the storage connection area 103b and the bit line connection area 103a may include at least one of doped n-type impurities, for example, phosphorous (P), arsenic (As), antimony (Sb), or bismuth (Bi). When a transistor including each word line WL, and the bit line connection area 103a and the storage connection area 103b adjacent thereto is a PMOS, each of the storage connection area 103b and the bit line connection area 103a may include doped p-type impurities, for example, at least one of boron (B) or gallium (Ga).

The bit line structure 140ST may include a cell conductive line 140 and a cell line capping film 144. The cell conductive line 140 may be disposed on the second substrate 100 on which the cell gate structure 110 has been formed and on the cell element isolation film 105. The cell conductive line 140 may intersect the cell element isolation film 105 and the cell active area ACT defined by the cell element isolation film 105. The cell conductive line 140 may be formed to intersect the cell gate structure 110. In this regard, the cell conductive line 140 may correspond to the bit line BL. For example, the cell conductive line 140 may be the bit line BL of FIG. 4.

The cell conductive line 140 may include, for example, at least one of impurity-doped semiconductor material, conductive metal silicide, conductive metal nitride, conductive metal oxide, a 2D material (two-dimensional material), or a metal. In the semiconductor device according to some embodiments, the two-dimensional material may be a metallic material and/or a semiconductor material. The two-dimensional material (2D material) may include a two-dimensional allotrope or a two-dimensional compound. For example, the 2D material may include at least one of graphene, molybdenum disulfide (MoS₂), molybdenum diselenide (MoSe₂), tungsten diselenide (WSe₂), and tungsten disulfide (WS₂). However, embodiments of the present disclosure are not limited thereto. In other words, the above-described two-dimensional materials are listed only by way of example. The two-dimensional material that may be included in the semiconductor memory device of the present disclosure is not limited to the above-described materials.

Although the cell conductive line 140 is illustrated as being embodied as a single film, this is only intended for convenience of illustration and embodiments of the present disclosure are not limited thereto. That is, unlike the illustrated example, the cell conductive line 140 may include a stack structure of a plurality of conductive films.

The cell line capping film 144 may be disposed on the cell conductive line 140. The cell line capping film 144 may extend in the second direction DR2 and along an upper surface of the cell conductive line 140. The cell line capping film 144 may include, for example, at least one of silicon nitride, silicon oxynitride, silicon carbonitride, or silicon oxycarbonitride.

In the semiconductor device according to some embodiments, the cell line capping film 144 may include silicon nitride. The cell line capping film 144 is illustrated as a single film. However, embodiments of the present disclosure are not limited thereto.

A bit line spacer 150 may be disposed on a sidewall of each of the cell conductive line 140 and the cell line capping film 144. The bit line spacer 150 extends in the second direction DR2.

Although the bit line spacer 150 is illustrated as being embodied as a single film, this is only intended for convenience of illustration and embodiments of the present disclosure are not limited thereto. That is, unlike the illustrated example, the bit line spacer 150 may have a multilayer structure. The bit line spacer 150 may include, for example, a silicon oxide film, a silicon nitride film, a silicon oxynitride film (SiON), a silicon oxycarbonitride film (SiOCN), air, or a combination thereof. However, embodiments of the present disclosure are not limited thereto.

A lower cell insulating film 135 may be disposed on the second substrate 100 and the cell element isolation film 105. More specifically, the lower cell insulating film 135 may be disposed on the upper surface 105US of the cell element isolation film and the second substrate 100 in an area which the bit line contact 146 and the storage contact 120 are not formed. The lower cell insulating film 135 may be disposed between the second substrate 100 and the cell conductive line 140, and may be disposed between the cell element isolation film 105 and the cell conductive line 140.

The lower cell insulating film 135 may be a single film. However, as illustrated, the lower cell insulating film 135 may have a multi-film structure including a first lower cell insulating film 136 and a second lower cell insulating film 137. For example, the first lower cell insulating film 136 may include silicon oxide, and the second lower cell insulating film 137 may include silicon nitride. However, embodiments of the present disclosure are not limited thereto. Unlike the illustrated example, the lower cell insulating film 135 may have a triple films structure including a silicon oxide film, a silicon nitride film, and a silicon oxide film. However, embodiments of the present disclosure are not limited thereto.

The bit line contact 146 may be disposed between the cell conductive line 140 and the second substrate 100. The cell conductive line 140 may be disposed on the bit line contact 146.

The bit line contact 146 may be disposed between the bit line connection area 103a of the cell active area ACT and the cell conductive line 140. The bit line contact 146 may be connected to the bit line connection area 103a.

The bit line contact 146 may include an upper surface 146US connected to the cell conductive line 140. Although a width in the first direction DR1 of the bit line contact 146 is illustrated as being constant as the bit line contact 146 extends away from an upper surface 146US of the bit line contact BLC, this is only intended for convenience of illustration and embodiments of the present disclosure are not limited thereto.

The bit line contact 146 may electrically connect the cell conductive line 140 and the second substrate 100 to each other. In this regard, the bit line contact 146 may correspond to the direct contact DC. The bit line contact 146 may include, for example, at least one of impurity-doped semiconductor material, conductive metal silicide, conductive metal nitride, conductive metal oxide, or metal.

In an area of the cell conductive line 140 where the bit line contact 146 is formed, the bit line spacer 150 may be disposed on the second substrate 100 and the cell element isolation film 105. The bit line spacer 150 may be disposed on a sidewall of each of the cell conductive line 140, the cell line capping film 144, and the bit line contact 146.

In the remaining area of the cell conductive line 140 where the bit line contact 146 is not formed, the bit line spacer 150 may be disposed on the lower cell insulating film 135. The bit line spacer 150 may be disposed on sidewall of each of the cell conductive line 140 and the cell line capping film 144.

A fence pattern 170 may be disposed on the second substrate 100 and the cell element isolation film 105. The fence pattern 170 may be formed so as to overlap the cell gate structure 110 formed in the second substrate 100 and the cell element isolation film 105.

The fence pattern 170 may be disposed between the bit line structures 140ST extending in the second direction DR2. The fence pattern 170 may include, for example, at least one of silicon oxide, silicon nitride, or silicon oxynitride.

The storage contact 120 may be disposed between the cell conductive lines 140 adjacent to each other in the first direction DR1. The storage contact 120 may be disposed on each of both opposing sides of the cell conductive line 140. More specifically, the storage contact 120 may be disposed between the bit line structures 140ST. The storage contact 120 may be disposed between the fence patterns 170 adjacent to each other in the second direction DR2.

The storage contact 120 may overlap the second substrate 100 and the cell element isolation film 105 in an area between the adjacent cell conductive lines 140. The storage contact 120 may be connected to the cell active area ACT. More specifically, the storage contact 120 may be connected to the storage connection area 103b. In this regard, the storage contact 120 may correspond to the buried contact BC of FIG. 4.

The storage contact 120 may include, for example, at least one of a semiconductor material doped with impurities, a conductive metal silicide, a conductive metal nitride, a conductive metal carbide, a conductive metal carbonitride, a conductive metal oxide, or a metal.

A storage pad 160 may be disposed on the storage contact 120. The storage pad 160 may be electrically connected to the storage contact 120. The storage pad 160 may be connected to the storage connection area 103b of the cell active area ACT. In this regard, the storage pad 160 may correspond to the landing pad LP.

The storage pad 160 may overlap a portion of an upper surface of the bit line structure 140ST. The storage pad 160 may include, for example, at least one of a semiconductor material doped with impurities, a conductive metal silicide, a conductive metal nitride, a conductive metal carbide, a conductive metal oxide, or a metal.

A pad isolation insulating film 180 may be disposed on the storage pad 160 and the bit line structure 140ST. For example, the pad isolation insulating film 180 may be disposed on the cell line capping film 144. The pad isolation insulating film 180 may define the storage pad 160 as each of a plurality of isolated areas.

The pad isolation insulating film 180 does not cover an upper surface 160US of the storage pad 160. The pad isolation insulating film 180 may fill a pad isolation recess PSS. The pad isolation recess may isolate the adjacent storage pads 160 from each other. For example, the upper surface 160US of the storage pad 160 may be coplanar with an upper surface 180US of the pad isolation insulating film PDL. However, embodiments of the present disclosure are not limited thereto.

The pad isolation insulating film 180 may include an insulating material, and may electrically isolate the plurality of storage pads 160 from each other. For example, the pad isolation insulating film 180 may include, for example, at least one of silicon oxide, silicon nitride, silicon oxynitride, silicon oxycarbonitride, or silicon carbonitride. However, embodiments of the present disclosure are not limited thereto.

A first etch stop film 196 may be disposed on the upper surface 160US of the storage pad 160 and the upper surface 180US of the pad isolation insulating layer PDL. The first etch stop film 196 may include, for example, at least one of silicon nitride, silicon carbonitride, silicon oxycarbonitride, silicon oxycarbide, or silicon boron nitride.

The first capacitor structure 190 may be disposed on the storage pad 160. The first capacitor structure 190 may be electrically connected to the storage pad 160. A portion of the first capacitor structure 190 may be disposed in the first etch stop film 196.

The first capacitor structure 190 may include a first lower electrode 191, a first lower inserted electrode film 192, a first lower interfacial electrode film 193, a first capacitor dielectric film 194, and a first upper electrode 195.

The first lower inserted electrode film 192, the first lower interfacial electrode film 193, and the first capacitor dielectric film 194 are disposed between the first lower electrode 191 and the first upper electrode 195. The first lower inserted electrode film 192 and the first lower interfacial electrode film 193 are disposed between the first lower electrode 191 and the first capacitor dielectric film 194. The first lower interfacial electrode film 193 is disposed between the first lower inserted electrode film 192 and the first capacitor dielectric film 194.

The first lower electrode 191 may be connected to the storage pad 160. For example, the first lower electrode 191 may contact at least a portion of the upper surface 160US of the storage pad 160 not covered with the first etch stop film 196. In FIG. 6, the first lower electrode 191 is illustrated as having a pillar shape extending from the upper surface 160US of the storage pad 160 in the fourth direction DR4. However, this is only an example. In another example, the first lower electrode 191 may have a cylinder shape extending from the upper surface 160US of the storage pad 160 in the fourth direction DR4.

At least one supporter pattern 60 and 65 may be disposed on the first etch stop film 196. The at least one supporter pattern 60 and 65 may support the first lower electrode 191.

For example, a plurality of supporter patterns 60 and 65 may be disposed on the first etch stop film 196. The plurality of supporter patterns 60 and 65 may include a first supporter pattern 60 and a second supporter pattern 65 sequentially arranged in the fourth direction DR4 while being disposed on the first etch stop film 196.

The first supporter pattern 60 and the second supporter pattern 65 may be spaced apart from the first etch stop film 196 in the fourth direction DR4. The first supporter pattern 60 and the second supporter pattern 65 may be spaced apart from each other in the fourth direction DR4.

Each of the first supporter pattern 60 and the second supporter pattern 65 may be in contact with a portion of the first lower electrode 191. Each of the first supporter pattern 60 and the second supporter pattern 65 may contact a sidewall of the first lower electrode 191. Although it is illustrated that the number of supporter patterns in contact with the first lower electrode 191 is two, this is only for convenience of illustration, and embodiments of the present disclosure are not limited thereto.

The second supporter pattern 65 is described by way of example. The second supporter pattern 65 may include a first surface 65_S1 and a second surface 65_S2 opposite to each other in the fourth direction DR4. The second surface 65_S2 of the second supporter pattern may face the cell conductive line 140. The second supporter pattern 65 may include a sidewall 65_SS connecting the first surface 65_S1 of the second supporter pattern to the second surface 65_S2 of the second supporter pattern. The sidewall 65_SS of the second supporter pattern SP2 may be in contact with the first lower electrode 191. Like the second supporter pattern 65 as described above, the first supporter pattern 60 may include a first surface, a second surface, and a sidewall.

Each of the first supporter pattern 60 and the second supporter pattern 65 may include, for example, at least one of silicon nitride, silicon carbonitride, silicon boron nitride, silicon carbonitride, silicon oxynitride, or silicon oxycarbonitride.

The first lower inserted electrode film 192 may be disposed on the first lower electrode 191. The first lower inserted electrode film 192 is in contact with the first lower electrode 191.

Since the first lower inserted electrode film 192 is formed by oxidizing the first lower electrode 191, the first lower inserted electrode film 192 is not disposed on the first supporter pattern 60 and the second supporter pattern 65. For example, the first lower inserted electrode film 192 is not disposed on the first surface of the first supporter pattern 60, the second surface of the first supporter pattern 60, the first surface 65_S1 of the second supporter pattern, and the second surface 65_S2 of the second supporter pattern. The first lower inserted electrode film 192 is not disposed on the upper surface of the first etch stop film 196.

The first lower interfacial electrode film 193 may be disposed on the first lower electrode 191, the first supporter pattern 60 and the second supporter pattern 65. The first lower interfacial electrode film 193 may be disposed on the first lower inserted electrode film 192.

The first lower interfacial electrode film 193 may extend along a sidewall and an upper surface of the first lower electrode 191. The first lower interfacial electrode film 193 may extend along the first surface of the first supporter pattern 60, the second surface of the first supporter pattern 60, the first surface 65_S1 of the second supporter pattern, and the second surface 65_S2 of the second supporter pattern. The first lower interfacial electrode film 193 may extend along the upper surface of the first etch stop film 196.

The first lower interfacial electrode film 193 may be in contact with the first lower inserted electrode film 192. The first lower interfacial electrode film 193 may contact the first supporter pattern 60, the second supporter pattern 65, and the first etch stop film 196.

The first capacitor dielectric film 194 may be disposed on the first lower interfacial electrode film 193. The first capacitor dielectric film 194 may extend along a profile of the first lower interfacial electrode film 193. The first capacitor dielectric film 194 may be in contact with the first lower interfacial electrode film 193.

For example, the first capacitor dielectric film 194 may extend along the first surface of the first supporter pattern 60, the second surface of the first supporter pattern 60, the first surface 65_S1 of the second supporter pattern, and the second surface 65_S2 of the second supporter pattern.

The first lower inserted electrode film 192, the first lower interfacial electrode film 193, and the first capacitor dielectric film 194 may be disposed on the sidewall and the upper surface of the first lower electrode 191. The first lower interfacial electrode film 193 and the first capacitor dielectric film 194 may be disposed on the first surface of the first supporter pattern 60, the second surface of the first supporter pattern 60, the first surface 65_S1 of the second supporter pattern, and the second surface 65_S2 of the second supporter pattern.

The first upper electrode 195 may be disposed on the first capacitor dielectric film 194. The first upper electrode 195 may fill a space defined between the first lower electrodes 191 adjacent to each other. The first upper electrode 195 may fill an area between the first supporter pattern 60 and the second supporter pattern 65 and an area between the first supporter pattern 60 and the first etch stop film 196.

The first capacitor structure 190 may correspond to the capacitor structure CS as described above with reference to FIGS. 1 to 3. The first lower electrode 191, the first lower inserted electrode film 192, the first lower interfacial electrode film 193, the first capacitor dielectric film 194, and the first upper electrode 195 may correspond to the lower electrode 30, the lower inserted electrode film 32, the lower interfacial electrode film 34, the capacitor dielectric film 40, and the upper electrode 50, respectively. The materials and crystal structures included in the first lower electrode 191, the first lower inserted electrode film 192, the first lower interfacial electrode film 193, the first capacitor dielectric film 194, and the first upper electrode 195 may be substantially the same as those of the lower electrode 30, the lower inserted electrode film 32, the lower interfacial electrode film 34, the capacitor dielectric film 40, and the upper electrode 50 as described above.

In FIGS. 9 to 11, the first lower inserted electrode film 192, the first lower interfacial electrode film 193, and the first capacitor dielectric film 194 may be sequentially arranged along a circumference of the first lower electrode 191. The first capacitor dielectric film 194 may include a plurality of crystal grains. A portion R1 of FIG. 9 and a portion R2 of FIG. 9 may have different crystal grains.

Each crystal grain included in the first capacitor dielectric film 194 may include a crystal plane 194_CXP grown in the crystal orientation 194_CXD. The crystal plane 194_CXP of the first capacitor dielectric film may be a crystal plane of the first capacitor dielectric film 194. The crystal orientation 194_CXD of the first capacitor dielectric film may be an orientation in which the preferred growth crystal plane of the first capacitor dielectric film 194 is grown. On the first lower electrode 191, the first capacitor dielectric film 194 may have a (110) plane as a preferred growth crystal plane. Each crystal grain included in the first capacitor dielectric film 194 may include the plane (110) grown in the orientation as a preferred growth orientation.

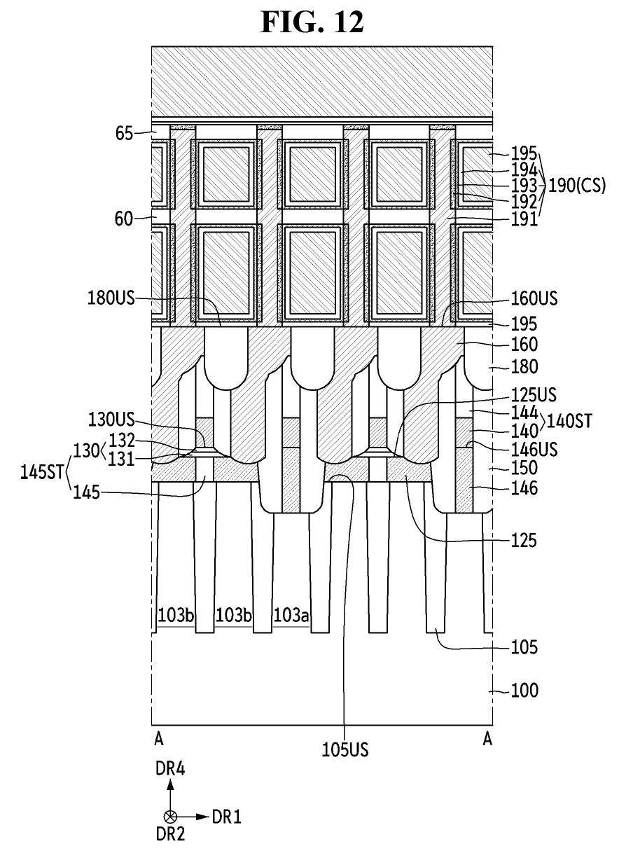

FIG. 12 is a diagram for illustrating a semiconductor device according to some embodiments. For convenience of description, differences thereof from those as described above with reference to FIGS. 4 to 11 will be mainly described.

Referring to FIG. 12, in the semiconductor device according to some embodiments, a node contact pad 125 may be disposed at a position of the storage contact 120.

The node contact pad 125 may be disposed on the second substrate 100. The node contact pad 125 may be disposed on the storage connection area 103b of the cell active area ACT. The node contact pad 125 is connected to the storage connection area 103b.

Based on the upper surface 105US of the cell element isolation film ST, a vertical level of an upper surface 125US of the node contact pad NP may be lower than a vertical level of the upper surface 146US of the bit line contact BC. Based on the upper surface 105US of the cell element isolation film ST, a vertical level of the upper surface 125US of the node contact pad NP may be lower than a vertical level of a bottom surface of the cell conductive line 140.

The node contact pad 125 may electrically connect the first capacitor structure 190 and the second substrate 100 to each other. In this regard, the node contact pad 125 may correspond to a node pad XP of FIG. 4.

The node contact pad 125 may include, for example, at least one of impurity-doped semiconductor material, conductive metal silicide, conductive metal nitride, conductive metal oxide, or metal.

A pad isolation structure 145ST may isolate the node contact pad 125 adjacent to each other in the first direction DR1 from each other. Although not shown, the pad isolation structure 145ST may isolate the node contact pad 125 adjacent to each other in the second direction DR2 from each other. The pad isolation structure 145ST may cover the upper surface 125US of the node contact pad NP.

The pad isolation structure 145ST may include a pad isolation pattern 145 and an upper cell insulating film 130. The upper cell insulating film 130 may be disposed on the pad isolation pattern 145.

When the node contact pad 125 includes a first node contact pad and a second node contact pad spaced apart from each other in the first direction DR1, the pad isolation pattern 145 may isolate the first node contact pad and the second node contact pad from each other in the first direction DR1. Although not shown, the pad isolation pattern 145 may also isolate the node contact pads 125 adjacent to each other in the second direction DR2 from each other.

The upper cell insulating layer 130 may cover the upper surface 125US of the node contact pad NP. When the node contact pad 125 includes the first node contact pad and the second node contact pad spaced apart from each other in the first direction DR1, the upper cell insulating layer 130 may cover the upper surface of the first node contact pad and the upper surface of the second node contact pad.

The upper surface 130US of the upper cell insulating film UCL may be coplanar with the upper surface 146US of the bit line contact BLC. That is, a vertical level of the upper surface 130US of the upper cell insulating layer UCL may be equal to a vertical level of the upper surface 146US of the bit line contact BC, based on the upper surface 105US of the cell element isolation film ST.

The cell conductive line 140 may be disposed on an upper surface of the pad isolation structure 145ST. The cell conductive line 140 may be disposed on the upper surface 130US of the upper cell insulating film. An upper surface of the pad isolation structure 145ST may be an upper surface 130US of the upper cell insulating film. An upper surface of the pad isolation structure 145ST may be coplanar with a bottom surface of the cell conductive line 140. Although not shown, the pad isolation pattern 145 and the upper cell insulating film 130 may be disposed between the bit line contacts 146 adjacent to each other in the second direction DR2.

The pad isolation pattern 145 may include, for example, silicon nitride, silicon oxynitride, silicon oxide, silicon carbonitride, silicon oxycarbonitride, or a combination thereof. The upper cell insulating film 130 may be a single film. However, as illustrated, the upper cell insulating film 130 may have a multi film structure including the first upper cell insulating film 131 and the second upper cell insulating film 132. For example, the first upper cell insulating film 131 may include a silicon oxide film, and the second upper cell insulating film 132 may include a silicon nitride film. However, embodiments of the present disclosure are not limited thereto. A width in the first direction DR1 of the upper cell insulating film 130 is illustrated as decreasing as the upper cell insulating film 130 extends away from the second substrate 100. However, embodiments of the present disclosure are not limited thereto.

The storage pad 160 may be disposed on each of the node contact pads 125. The storage pad 160 may be electrically connected to the node contact pad 125.

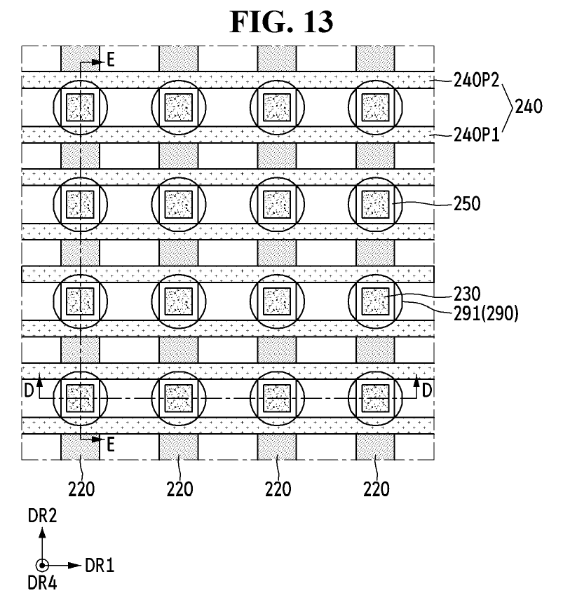

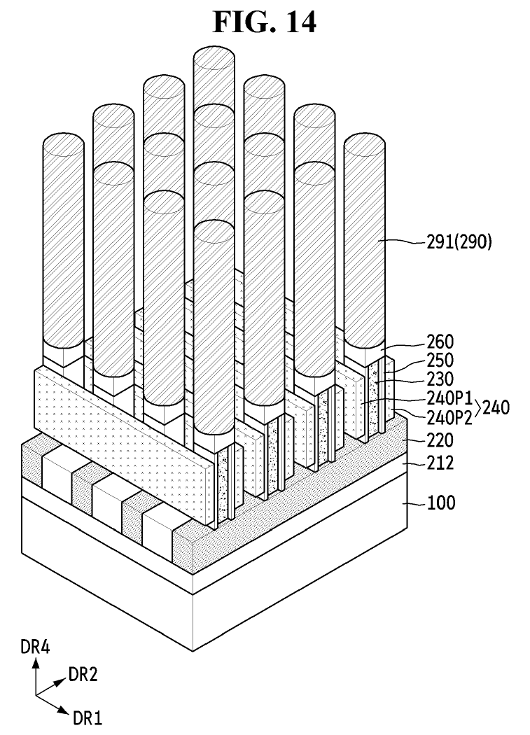

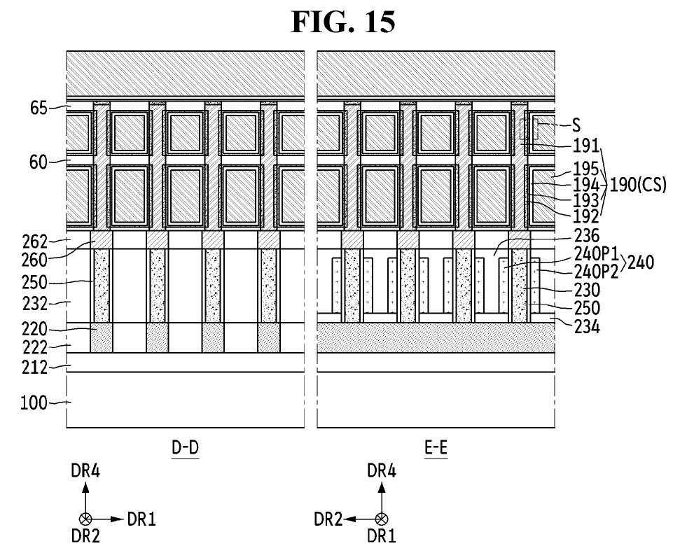

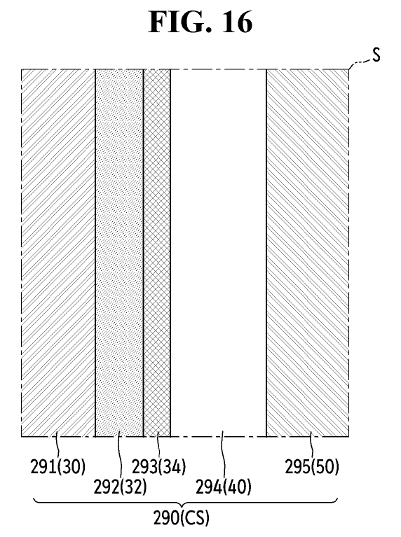

FIG. 13 is a layout diagram for illustrating a semiconductor device according to some embodiments. FIG. 14 is a perspective view illustrating the semiconductor device of FIG. 13. FIG. 15 is a cross-sectional view taken along lines D-D and E-E of FIG. 13. FIG. 16 is an enlarged view for illustrating a portion S of FIG. 15.

Referring to FIGS. 13 to 16, a semiconductor device according to some embodiments may include a second substrate 100, a plurality of first conductive lines 220, a channel layer 230, a gate electrode 240, a gate insulating film 250, and a second capacitor structure 290.

The semiconductor device according to some embodiments may be a memory device including a vertical channel transistor (VCT). The vertical channel transistor may refer to a structure in which a channel length of the channel layer 230 extends from the second substrate 100 in a vertical direction (fourth direction DR4).

A first lower insulating film 212 may be disposed on the second substrate 100. A plurality of first conductive lines 220 may be spaced apart from each other in the first direction DR1 and may extend in the second direction DR2 while being disposed on the first lower insulating film 212. A plurality of first insulating patterns 222 may be disposed on the first lower insulating film 212 so as to fill a space between adjacent ones of the plurality of first conductive lines 220. The plurality of first insulating patterns 222 may extend in the second direction DR2. Upper surfaces of the plurality of first insulating patterns 222 may be coplanar with upper surfaces of the plurality of first conductive lines 220. The plurality of first conductive lines 220 may function as the bit lines BL.

Each of the plurality of first conductive lines 220 may include a doped semiconductor material, a metal, a conductive metal nitride, a conductive metal silicide, a conductive metal oxide, or a combination thereof. For example, each of the plurality of first conductive lines 220 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrO RuO, or a combination thereof. However, embodiments of the present disclosure are not limited thereto. Each of the plurality of first conductive lines 220 may include a single layer or multiple layers made of the above-described materials. In some embodiments, each of the plurality of first conductive lines 220 may include graphene, carbon nanotubes, or a combination thereof.

The channel layers 230 may be arranged in a matrix form and may be spaced apart from each other in the first direction DR1 and the second direction DR2 and may be disposed on the plurality of first conductive lines 420. The channel layer 230 may have a first width along the first direction DR1 and a first vertical dimension along the fourth direction DR4. In this regard, the fourth direction DR4 may be, for example, a direction perpendicular to the upper surface of the second substrate 100. The first vertical dimension may be larger than the first width. For example, the first vertical dimension may be about 2 to 10 times of the first width. However, the present disclosure is not limited thereto. A bottom portion of the channel layer 230 may function as a first source/drain area, and an upper portion of the channel layer 230 may function as a second source/drain area, and a portion of the channel layer 230 between the first and second source/drain areas may function as a channel area.

In some embodiments, the channel layer 230 may include an oxide semiconductor. For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or combinations thereof. The channel layer 230 may include a single layer or multiple layers made of the oxide semiconductor. In some embodiments, the channel layer 230 may have a bandgap energy greater than that of silicon. For example, the channel layer 230 may have a bandgap energy of about 1.5 eV to about 5.6 eV. For example, the channel layer 230 may have optimal channel performance when it has a bandgap energy of about 2.0 eV to 4.0 eV. For example, the channel layer 230 may be made of polycrystalline or amorphous. However, the present disclosure is not limited thereto. In some embodiments, the channel layer 230 may be polycrystalline or amorphous. However, embodiments of the present disclosure are not limited thereto. In another example, the channel layer 230 may include graphene, carbon nanotubes, or a combination thereof. In still another example, the channel layer 230 may include a silicon-based semiconductor material. The channel layer 230 may include a single crystal semiconductor material, and may include, for example, single crystal silicon or single crystal silicon-germanium. However, embodiments of the present disclosure are not limited thereto.

The gate electrode 240 may extend in the first direction DR1 and may be disposed on both opposing sidewalls of the channel layer 230. The gate electrode 240 may include a first sub-gate electrode 240P1 facing a first sidewall of the channel layer 230 and a second sub-gate electrode 240P2 facing a second sidewall opposite the first sidewall of the channel layer 230. As one channel layer 230 is disposed between the first sub-gate electrode 240P1 and the second sub-gate electrode 240P2, the semiconductor device may have a dual gate transistor structure. However, the technical idea of the present disclosure is not limited thereto, and the second sub-gate electrode 240P2 may be omitted and only the first sub-gate electrode 240P1 facing the first sidewall of the channel layer 230 may be formed to achieve a single gate transistor structure. The gate electrode 240 may function as the word line WL of the memory cell. A material included in the gate electrode 240 may refer to the description of the material included in the cell gate electrode 112.

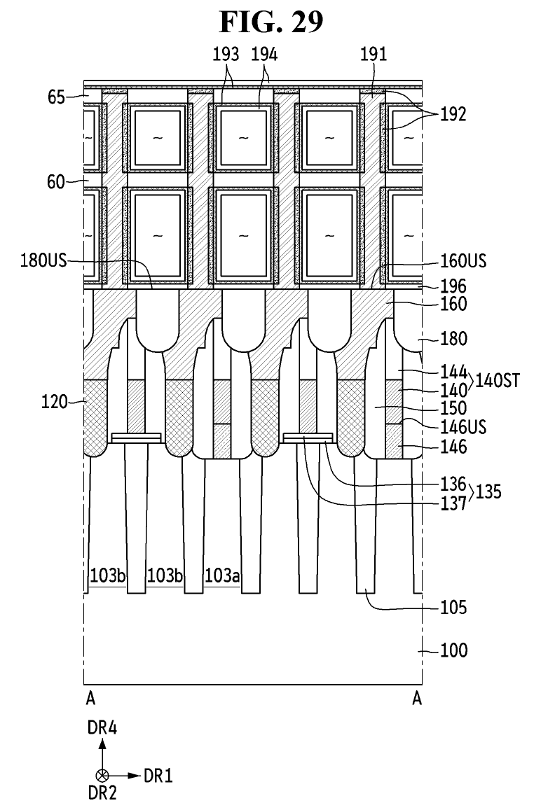

The gate insulating film 250 may surround a sidewall of the channel layer 230 and may be interposed between the channel layer 230 and the gate electrode 240. For example, as shown in FIG. 29, an entirety of the sidewall of the channel layer 230 may be surrounded with the gate insulating film 250. A portion of the sidewall of the gate electrode 240 may be in contact with the gate insulating film 250. In further some embodiments, the gate insulating film 250 may extend in an extension direction of the gate electrode 240, that is, the first direction DR1, and only two sidewalls facing the gate electrode 240 among the sidewalls of the channel layer 230 may be in contact with the gate insulating film 250. In some embodiments, the gate insulating film 250 may include a silicon oxide, a silicon oxynitride, a high-k material having a dielectric constant higher than that of the silicon oxide, or a combination thereof.

A plurality of second insulating patterns 232 may be respectively disposed on the plurality of first insulating patterns 222 and may extend along the second direction DR2. The channel layer 230 may be disposed between two adjacent second insulating patterns 232 among the plurality of second insulating pattern 232. Further, a first buried layer 234 and a second buried layer 236 may be disposed between two adjacent second insulating patterns 232 and in a space between two adjacent channel layers 230. The first buried layer 234 may be disposed at a bottom portion of the space between two adjacent channel layers 230, and the second buried layer 236 may be formed on the first buried layer 234 so as to fill the remainder of the space between two adjacent channel layers 230. An upper face of the second buried layer 236 may be coplanar with an upper surface of the channel layer 230, and the second buried layer 236 may cover an upper surface of the gate electrode 240. Alternatively, the plurality of second insulating patterns 232 may be continuous and monolithic with the plurality of first insulating patterns 222, respectively, or the second buried layer 236 may be continuous and monolithic with the first buried layer 234.

A capacitor contact 260 may be disposed on the channel layer 230. The capacitor contact 260 may vertically overlap the channel layer 230. The capacitor contacts 260 may be arranged in a matrix form and may be spaced apart from each other in the first direction DR1 and the second direction DR2. The capacitor contact 260 may be made of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrO, RuO, or a combination thereof. However, the present disclosure is not limited thereto. An upper insulating film 262 may surround a sidewall of the capacitor contact 260 while being disposed on the plurality of second insulating patterns 232 and the second buried layer 236.

A second etch stop film 270 may be disposed on the upper insulating film 262. The second capacitor structure 290 may be disposed on the second etch stop film 270.

The second capacitor structure 290 may include a second lower electrode 291, a second lower inserted electrode film 292, a second lower interfacial electrode film 293, a second capacitor dielectric film 294, and a second upper electrode 295.

The second lower electrode 291 may extend through the second etch stop film 270 so as to be electrically connected to the upper surface of the capacitor contact 260. The second lower electrode 291 may be formed in a pillar shape extending in the fourth direction DR4. However, embodiments of the present disclosure are not limited thereto. In some embodiments, the second lower electrode 291 may be disposed to vertically overlap the capacitor contact 260. The second lower electrodes 191 may be arranged in a matrix form and may be spaced apart from each other in the first direction DR1 and the second direction DR2. Alternatively, a landing pad may be further disposed between the capacitor contact 260 and the second lower electrode 291 such that the second lower electrodes 291 may be arranged in a hexagonal manner.

At least one supporter pattern 60 and 65 may be disposed on the second etch stop film 270. The at least one supporter pattern 60 and 65 may support the second lower electrode 291. The first supporter pattern 60 and the second supporter pattern 65 have been described with reference to FIGS. 4 to 12, and thus will not be described below.

Unlike the illustrated example, the semiconductor device according to some embodiments may not include at least one or more supporter patterns 60 and 65 supporting the sidewall of the second lower electrode 291.

The second lower inserted electrode film 292 may be disposed on the second lower electrode 291. The second lower inserted electrode film 292 is in contact with the second lower electrode 291. The second lower inserted electrode film 292 is not disposed on the second supporter pattern 60 and the second supporter pattern 65.

The second lower interfacial electrode film 293 may be disposed on the second lower electrode 291, the first supporter pattern 60 and the second supporter pattern 65. The second lower interfacial electrode film 293 may be disposed on the second lower inserted electrode film 292. The second lower interfacial electrode film 293 may be in contact with the second lower inserted electrode film 292. The second lower interfacial electrode film 293 may be in contact with the first supporter pattern 60, the second supporter pattern 65, and the second etch stop film 270.

The second capacitor dielectric film 294 may be disposed on the second lower interfacial electrode film 293. The second capacitor dielectric film 294 may extend along the profile of the second lower interfacial electrode film 293. The second capacitor dielectric film 294 may be in contact with the second lower interfacial electrode film 293.

The second upper electrode 295 may be disposed on the second capacitor dielectric film 294.

The second capacitor structure 290 may correspond to the capacitor structure CS as described above with reference to FIGS. 1 to 3. The second lower electrode 291, the second lower inserted electrode film 292, the second lower interfacial electrode film 293, the second capacitor dielectric film 294, and the second upper electrode 295 may correspond to the lower electrode 30, the lower inserted electrode film 32, the lower interfacial electrode film 34, the capacitor dielectric film 40, and the upper electrode 50, respectively. As illustrated in FIG. 16, the second lower inserted electrode film 292, the second lower interfacial electrode film 293, and the second capacitor dielectric film 294 may be sequentially stacked on the second lower electrode 291.

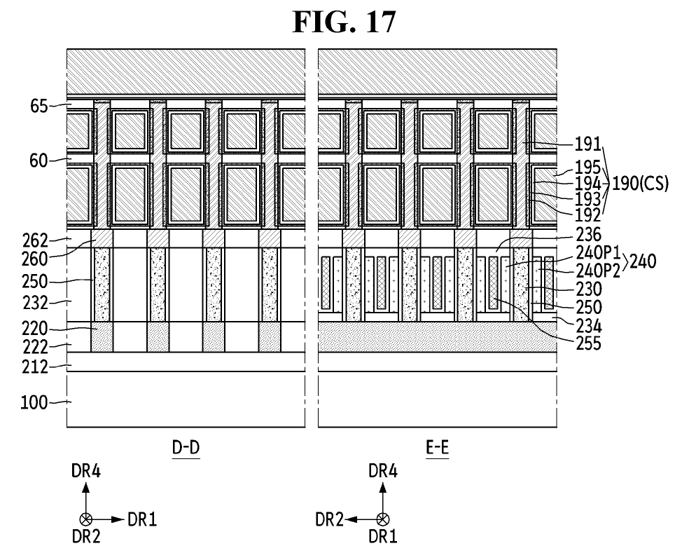

FIG. 17 is a diagram for illustrating a semiconductor device according to some embodiments. For convenience of description, differences thereof from those as described above with reference to FIGS. 13 to 16 will be mainly described.

Referring to FIG. 17, the semiconductor device according to some embodiments may further include a back gate electrode 255.

The back gate electrode 255 may be disposed between the channel layers 230 adjacent to each other in the second direction DR2. For example, the back gate electrode 255 may be disposed in the second buried layer 236.

A voltage may be applied to the back gate electrode 255 so that a threshold voltage of the vertical channel transistor may be adjusted. The threshold voltage of the vertical channel transistor is adjusted, thereby preventing a leakage current characteristic from being deteriorated.

The back gate electrode 255 may include a conductive material, and may include, for example, at least one of a conductive semiconductor material, a conductive metal nitride, a conductive metal silicon nitride, a metal carbonitride, a conductive metal silicide, a conductive metal oxide, a two-dimensional material, and a metal.

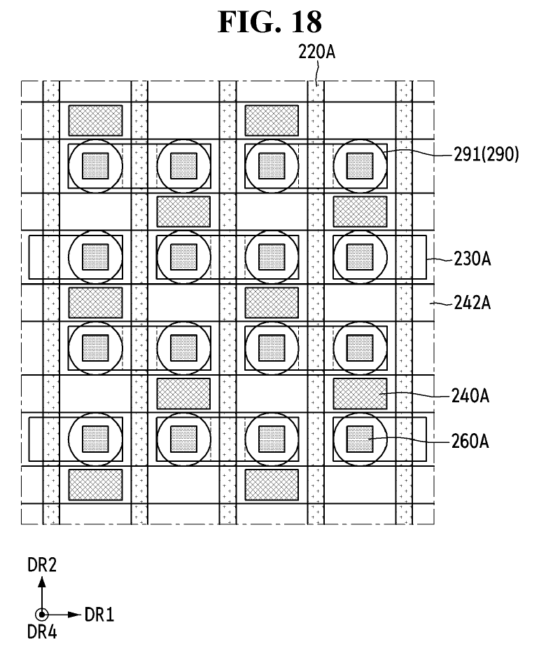

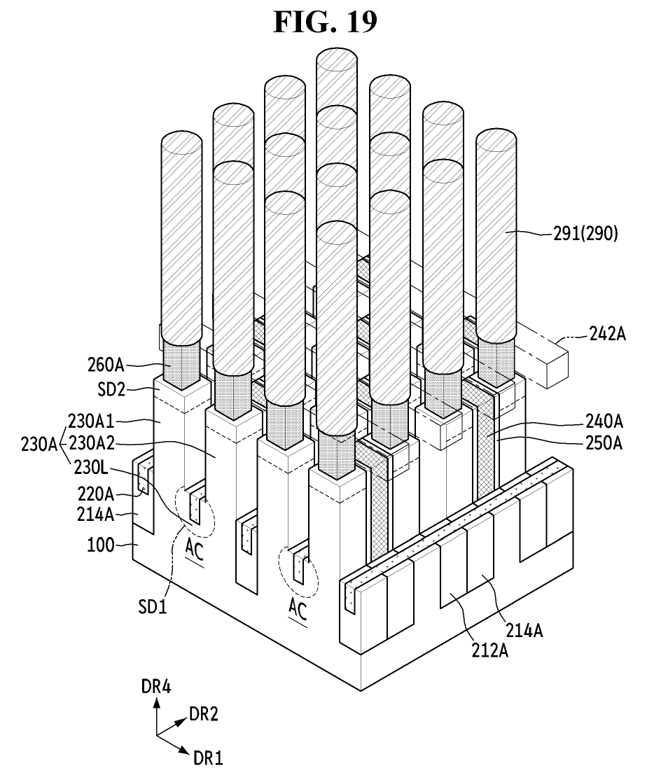

FIG. 18 is a layout diagram for illustrating a semiconductor device according to some embodiments. FIG. 19 is a perspective view illustrating the semiconductor device of FIG. 18.

Referring to FIGS. 18 and 19, the semiconductor device according to some embodiments may include a second substrate 100, a plurality of first conductive lines 220A, a channel structure 230A, a contact gate electrode 240A, a plurality of second conductive lines 242A, and a second capacitor structure 290. The semiconductor device according to some embodiments may be a memory device including a vertical channel transistor (VCT).

A plurality of active areas AC may be disposed in the second substrate 100 and may be defined by a first element isolation pattern 212A and a second element isolation pattern 214A. The channel structure 230A may be disposed in each active area AC. The channel structure 230A may include a first active pillar 230A1 and a second active pillar 230A2 extending in a vertical direction, respectively, and a connection portion 230L connected to a bottom portion of the first active pillar 2L and a bottom portion of the second active pillar 230A2. A third source/drain area SD1 may be disposed in the connection portion 230L. A fourth source/drain area SD2 may be disposed in a top portion of each of the first and second active pillars 230A1 and 230A2. Each of the first active pillar 230A1 and the second active pillar 230A2 may constitute an independent unit memory cell.

Each of the plurality of first conductive lines 220A may extend so as to intersect each of the plurality of active areas AC, and may extend, for example, in the second direction DR2. One first conductive line 220A among the plurality of first conductive lines 220A may be disposed on the connection portion 230L and between the first active pillar 230A2 and the second active pillar 230A2. One first conductive line 220A may be disposed on the third source/drain area SD1. Another first conductive line 220A adjacent to one first conductive line 220A may be disposed between two channel structures 230A. One first conductive line 220A of the plurality of first conductive lines 220A One first conductive line 220A among the plurality of first conductive lines 220A may function as a common bit-line of two unit memory cells respectively including the first active pillar 230A1 and the second active pillar 230A2 respectively disposed on both opposing sides of said one first conductive line 220A.

One contact gate electrode 240A may be disposed between two channel structures 230A adjacent to each other in the second direction DR2. For example, the contact gate electrode 240A may be disposed between the first active pillar 230A1 included in one channel structure 230A and the second active pillar 230A2 of another channel structure 230A adjacent thereto. One contact gate electrode 240 may be shared by the first active pillar 230A1 and the second active pillar 230A2 respectively disposed on both sidewalls thereof. A gate insulating film 250A may be disposed between the contact gate electrode 240A and the first active pillar 230A1 and between the contact gate electrode 240A and the second active pillar 230A2. A plurality of second conductive lines 242A may extend in the first direction DR1 and may be disposed on an upper face of the contact gate electrode 240A. Each of the plurality of second conductive lines 242A may function as a word-line of a memory cell.

A capacitor contact 260A may be disposed on the channel structure 230A. The capacitor contact 260A may be disposed on the fourth source/drain area SD2, and the second capacitor structure 290 may be disposed on the capacitor contact 260A.

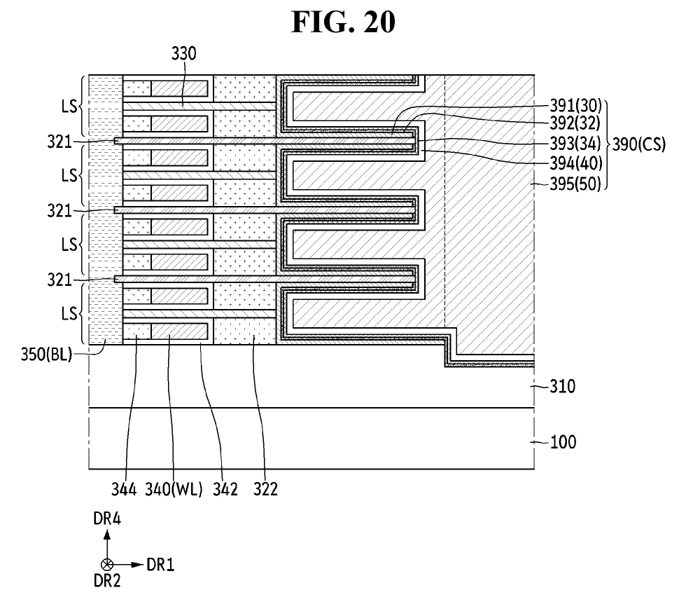

FIG. 20 is a diagram for illustrating a semiconductor device according to some embodiments. For reference, FIG. 20 may be a cross-sectional view of a semiconductor device.

Referring to FIG. 20, the semiconductor device according to some embodiments may include a second substrate 100, a lower structure 310 on the second substrate 100, a plurality of structures LS and a plurality of first insulating layers 321 alternately stacked on top of each other while being disposed on the second substrate 100, and a second conductive pattern 350.

Each of the plurality of structures LS may include an active layer 330 extending in the first direction DR1, a first conductive pattern 340 intersecting the active layer 330 and extending in the second direction DR2 perpendicular to the first direction DR1, a gate insulating pattern 342 between the active layer 330 and the first conductive pattern 340, a gate capping layer 344 between the first conductive pattern 340 and the second conductive pattern 350, a third lower electrode 391 of a third capacitor structure 390, and a second insulating layer 322 between the first conductive pattern 340 and the third lower electrode 391.

The third capacitor structure 390 may include the third lower electrode 391, a third lower inserted electrode film 392, a third lower interfacial electrode film 393, a third capacitor dielectric film 394, and a third upper electrode 395. The third lower inserted electrode film 392, the third lower interfacial electrode film 393, and the third capacitor dielectric film 394 are disposed between the third lower electrode 391 and the third upper electrode 395. The third lower inserted electrode film 392 and the third lower interfacial electrode film 393 are disposed between the third lower electrode 391 and the third capacitor dielectric film 394. The third lower interfacial electrode film 393 is disposed between the third lower inserted electrode film 392 and the third capacitor dielectric film 394.

The lower structure 310 may be disposed on the second substrate 100. The plurality of structures LS and the plurality of first insulating layers 321 may be stacked on the lower structure 310. The lower structure 310 may include an element area on the second substrate 100 and an insulating area IR covering the element area. The insulating area may be composed of insulating layers including an insulating material, for example, at least one of silicon oxide, silicon nitride, silicon oxynitride, and silicon oxycarbide.

The plurality of structures LS and the plurality of first insulating layers 321 may constitute a mold structure on the second substrate 100. Each of the plurality of structures LS may be disposed between adjacent ones of the plurality of first insulating layers 321, and the plurality of structures LS may be spaced apart from each other in the fourth direction DR4 via each of the plurality of first insulating layers 321. The first insulating layer 321 may extend in the first direction DR1, and an end thereof may extend into the second conductive pattern 350. The second insulating layer 322 may be disposed between the first insulating layer 321 and the active layer 330 and between the first conductive pattern 340 and the third capacitor structure 390. Each of the first insulating layer 321 and the second insulating layer 322 may include an insulating material, for example, at least one of silicon oxide, silicon nitride, silicon oxynitride, and silicon oxycarbide. The first insulating layer 321 may extend horizontally in a length by larger than an extension length of the second insulating layer 322. A thickness of the second insulating layer 322 may be greater than a thickness of the first insulating layer 321.

The active layer 330 may be disposed on the second substrate 100 and may horizontally extend in the first direction DR1. A plurality of active layers 330 may be stacked so as to be spaced apart from each other in the fourth direction DR4. The plurality of active layers 330 may be arranged in the second direction DR2. Each of the plurality of active layers 330 arranged in the fourth direction DR4 may be disposed between adjacent ones of the plurality of first insulating layers 321. The active layer 330 may have a linear shape, a bar shape, or a pillar shape that interests the first conductive pattern 340 and extends in the first direction DR1. The active layer 330 may include a semiconductor material, for example, silicon, germanium, or silicon-germanium.

The active layer 330 may include a first impurity area, a second impurity area, and a channel area. The first impurity area of the active layer 330 may be electrically connected to the second conductive pattern 350. The second impurity area of the active layer 330 may be electrically connected to the third lower electrode 391 of the third capacitor structure 390. A length in the first direction DR1 of the second impurity area of the active layer 330 may be greater than a length in the first direction DR1 of the first impurity area of the active layer 330. However, embodiments of the present disclosure are not limited thereto. The channel area of the active layer 330 may be disposed between the first impurity area of the active layer 330 and the second impurity area of the active layer 330. The channel area of the active layer 330 may overlap the first conductive pattern 340. The first impurity area of the active layer 330 and the second impurity area of the active layer 330 may be spaced apart from each other in the horizontal direction and disposed at the same level, and the channel area of the active layer 330 may be a horizontal channel area.

The first impurity area of the active layer 330 and the second impurity area of the active layer 330 may be formed by performing an ion implantation process or doping of impurities into the active layer 330. The first impurity area of the active layer 330 and the second impurity area of the active layer 330 may include n-type or p-type impurities.

A portion of the first impurity area of the active layer 330 may correspond to a source area of the transistor TR, a portion of the second impurity area of the active layer 330 may correspond to a drain area of the transistor TR, and the channel area of the active layer 330 may correspond to a channel of the transistor TR. A portion of the first impurity area of the active layer 330 may provide a first contact area for directly connecting the source area of the transistor to the second conductive pattern 350, that is, the bit line BL, while a portion of the second impurity area of the active layer 330 may provide a second contact area for directly connecting the drain area of the transistor to the information storage structure DS.

In another example, the active layers 330 may include an oxide semiconductor, for example, at least one of hafnium-silicon oxide (HSO), hafnium-zinc oxide (HZO), indium-zinc oxide (IZO), indium-gallium oxide (IGO), indium-tin oxide (ITO), indium-gallium-zinc oxide (IGZO), and indium-tin-zinc oxide (ITZO).

In still another example, the active layer 330 may include a two-dimensional material (2D material) in which atoms may form a predetermined crystal structure to constitute a channel of a transistor. The 2D material layer included in the active layer 330 may include at least one of a transition metal dichalcogenide (TMD) material layer, a black phosphorous material layer, and a hexagonal boron-nitride (nBN) material layer. For example, the two-dimensional material layer included in the active layer 330 may include at least one of BiOSe, Crl, WSe₂, MoS₂, TaS, WS, SnSe, ReS, β-SnTe, MnO, AsS, P (black), InSe, h-BN, GaSe, GaN, SrTiO, MXene, and Janus 2D materials, which may constitute a two-dimensional material layer.

The first conductive pattern 340 may be disposed on the second substrate 100 and may horizontally extend in the second direction DR2. A plurality of first conductive patterns 340 may be stacked so as to be spaced apart from each other in the fourth direction DR4, and a plurality of first conductive patterns 340 may be arranged in the first direction DR1. The first conductive pattern 340 may be disposed between the channel area 330c of the active layer 330 and the first insulating layer 321. The first conductive pattern 340 may be disposed on an upper surface and a lower surface of the active layer 330. The first conductive pattern 340 may have a linear shape, a bar shape, or a pillar shape that intersects the second conductive pattern 350 and extends in the second direction DR2. Although not shown, the plurality of first conductive patterns 340 stacked in the fourth direction DR4 in one memory cell may extend by different lengths in the second direction DR2 such that each of the plurality of first conductive patterns 340 provides a contact area as an exposed upper surface of each of the plurality of first conductive patterns.

The first conductive pattern 340 may include a conductive material, and the conductive material may include at least one of doped semiconductor material, conductive metal nitride, metal, or metal silicide. The first conductive pattern 340 may be a word line WL and may be referred to as a "gate electrode".

The gate insulating pattern 342 may be disposed between the first conductive pattern 340 and the active layer 330. The gate insulating pattern 342 may be formed in an inner space of a gap area formed by etching the second insulating layer 322 inwardly from a side surface thereof in an area between adjacent first insulating layers 321 and may be formed so as to have a substantially conformal thickness. The gate insulating pattern 342 may include silicon oxide, silicon nitride, or a high-k material.

The gate capping layer 344 may be disposed to fill a space obtained by removing a portion of the first conductive pattern 340 inwardly from the side surface thereof. For example, a side surface of the gate capping layer 344 may be in contact with a side surface of the first conductive pattern 340, and an upper surface and a lower surface thereof may be covered with the gate insulating pattern 342. The gate capping layer 344 may electrically insulate the first conductive pattern 340 from the second conductive pattern 350.

The second conductive pattern 350 may vertically extend in the fourth direction DR4 while being disposed on the second substrate 100. A plurality of second conductive patterns 350 may be arranged in the second direction DR2. The second conductive pattern 350 may be disposed adjacent to the first impurity area of the active layer 330 and a first end surface of the active layer 330. A plurality of active layers 330 stacked in the fourth direction DR4 may be electrically connected to one second conductive pattern 350. The second conductive pattern 350 may have a linear shape, a bar shape, or a pillar shape extending in the fourth direction DR4. Although not shown, the semiconductor device may further include an upper wiring disposed on the second conductive pattern 350, connected to the second conductive pattern 350, and extending in the first direction DR1. The second conductive pattern 350 may include at least one of a doped semiconductor material, a conductive metal nitride, a metal, or a metal silicide.

The third capacitor structure 390 may be disposed adjacent to the second impurity area of the active layer 330 and a second end surface of the active layer 330. The third capacitor structure 390 may be electrically connected to the active layer 330. The third lower electrode 391 may have a cylindrical shape. However, embodiments of the present disclosure are not limited thereto, and may the third lower electrode 391 have a pillar shape in some embodiments.

The third lower electrode 391 may be formed in an inner space of a gap area formed by etching the second insulating layer 322 inwardly from a side surface thereof and may be formed so as to have a substantially conformal thickness. The third lower electrode 391 may be in a state in which respective nodes of the structures LS are isolated from each other by depositing a conductive material and then removing a portion on a side surface of the first insulating layer 321.

The third lower inserted electrode film 392, the third lower interfacial electrode film 393, the third capacitor dielectric film 394, and the third upper electrode 395 may be sequentially stacked on the third lower electrode 391.

The third capacitor structure 390 may correspond to the capacitor structure CS described above with reference to FIGS. 1 to 3. The third lower electrode 391, the third lower inserted electrode film 392, the third lower interfacial electrode film 393, the third capacitor dielectric film 394, and the third upper electrode 395 may correspond to the lower electrode 30, the lower inserted electrode film 32, the lower interfacial electrode film 34, the capacitor dielectric film 40, and the upper electrode 50, respectively. The materials and crystal structures included in the third lower electrode 391, the third lower inserted electrode film 392, the third lower interfacial electrode film 393, the third capacitor dielectric film 394, and the third upper electrode 395 may be substantially the same as those of the lower electrode 30, the lower inserted electrode film 32, the lower interfacial electrode film 34, the capacitor dielectric film 40, and the upper electrode 50 as described above.

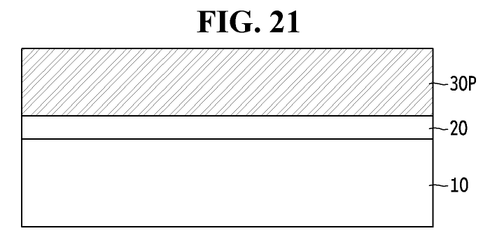

FIGS. 21 to 24 are diagrams of intermediate structures corresponding to intermediate steps of a method for manufacturing a semiconductor device according to some embodiments. For convenience of description, contents duplicate with those as described above with reference to FIGS. 1 to 3 will be briefly described or the descriptions thereof will be omitted.

Referring to FIG. 21, the lower insulating film 20 and a pre-lower electrode 30P may be formed on the first substrate 10.

The lower insulating film 20 may be formed on the substrate 10. The pre-lower electrode 30P may be formed on the lower insulating film 20. The pre-lower electrode 30P may include a first metal element (M1 of FIGS. 1 to 3). The pre-lower electrode 30P may include a metal film made of the first metal element M1 or a metal nitride film made of a nitride of the first metal element M1.

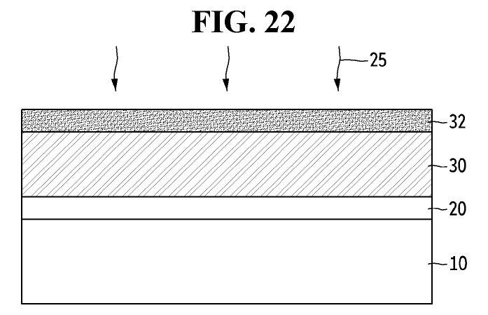

Referring to FIG. 22, the lower inserted electrode film 32 may be formed by oxidizing a portion of the pre-lower electrode 30P.

The lower inserted electrode film 32 may be formed using an oxidation process 25. The lower inserted electrode film 32 includes an oxide of the pre-lower electrode 30P. While the lower inserted electrode film 32 is formed, the rest of the pre-lower electrode 30P may be converted to the lower electrode 30.

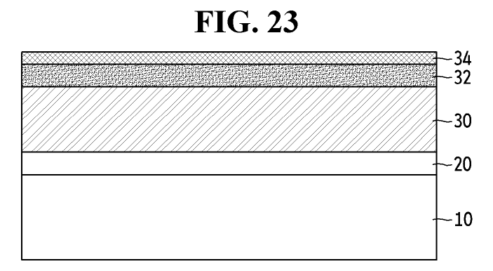

Referring to FIGS. 22 and 23, after the lower inserted electrode film 32 is formed, the lower interfacial electrode film 34 may be formed on the lower inserted electrode film 32.

The lower inserted electrode film 32 and the lower interfacial electrode film 34 may be formed in different processes. In other words, the lower inserted electrode film 32 may not be formed by oxidizing the pre-lower electrode 30P while the lower interfacial electrode film 34 is formed. Rather, the lower inserted electrode film 32 may be formed in a separate process different from that of the lower interfacial electrode film 34.

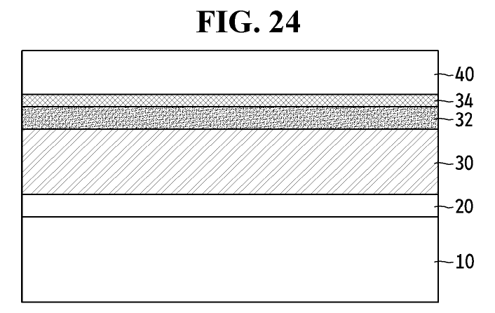

Referring to FIG. 24, the capacitor dielectric film 40 may be formed on the lower interfacial electrode film 34.

Subsequently, in FIG. 1, the upper electrode 50 may be formed on the capacitor dielectric film 40.

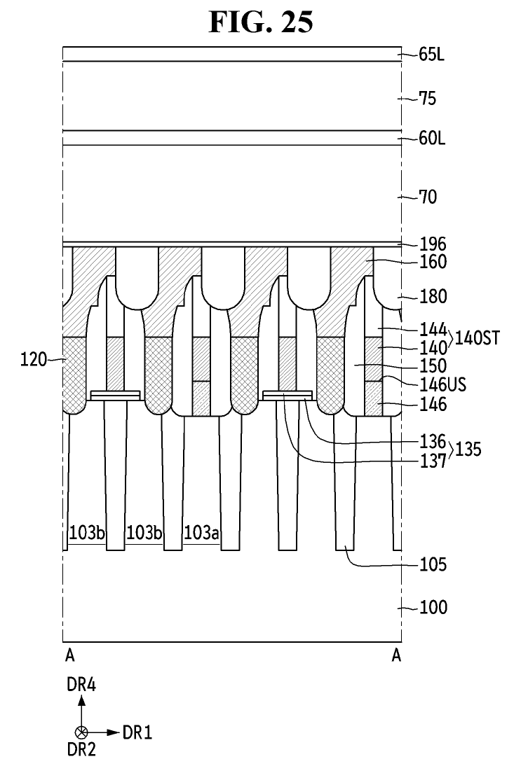

FIGS. 25 to 29 are diagrams of intermediate structures corresponding to intermediate steps of a method for manufacturing a semiconductor device according to some embodiments. For convenience of description, contents duplicate with those as described above with reference to FIGS. 6 to 11 will be briefly described or the descriptions thereof will be omitted.

Referring to FIG. 25, the plurality of bit line structures 140ST, the plurality of storage contacts 120, the plurality of bit line contacts 146, and the plurality of storage pads 160 may be formed on the second substrate 100.

The first etch stop film 196 may be formed on the storage pad 160 and the pad isolation insulating film 180.

A first mold layer 70, a first supporter film 60L, a second mold layer 75, and a second supporter film 65L may be sequentially formed on the first etch stop film 196. Each of the first mold layer 70 and the second mold layer 75 may include, but is not limited to, silicon oxide. Each of the first supporter film 60L and the second supporter film 65L may include an insulating material having an etch selectivity with respect to each of the first mold layer 70 and the second mold layer 75.

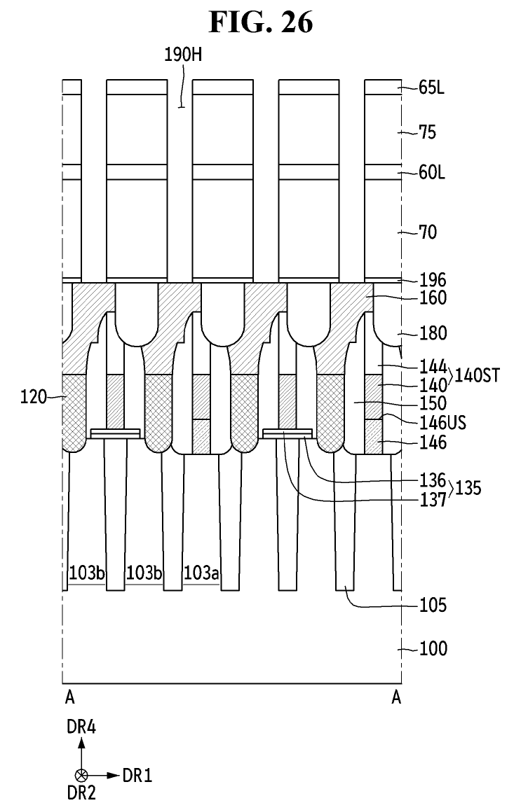

Referring to FIG. 26, a plurality of lower electrode holes 190H may be formed in the first mold layer 70, the first supporter film 60L, the second mold layer 75, and the second supporter film 65L.

Each of the lower electrode holes 190H may extend through the first mold layer 70, the first supporter film 60L, the second mold layer 75, and the second supporter film 65L. Each of the lower electrode holes 190H may extend through the first etch stop film 196 to expose the storage pad 160.

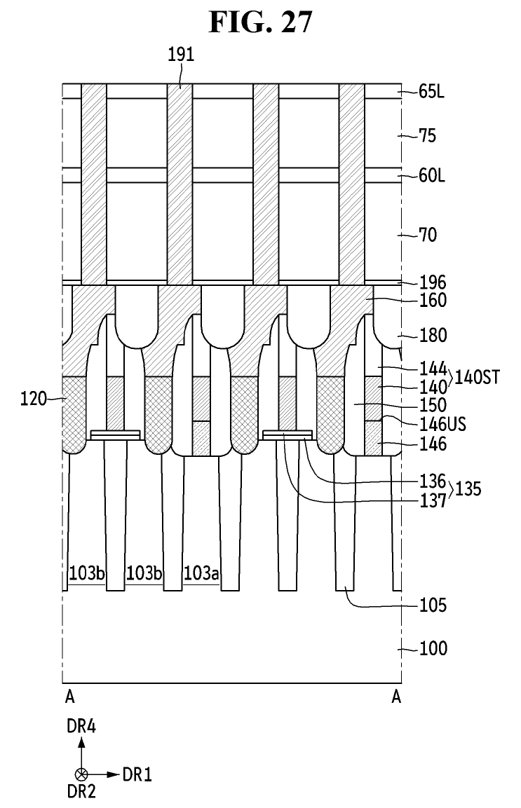

Referring to FIGS. 26 and 27, the first lower electrode 191 may be formed in the lower electrode hole 190H.

The first lower electrode 191 may fill the lower electrode hole 190H. The first lower electrode 191 may be connected to the storage pad 160.

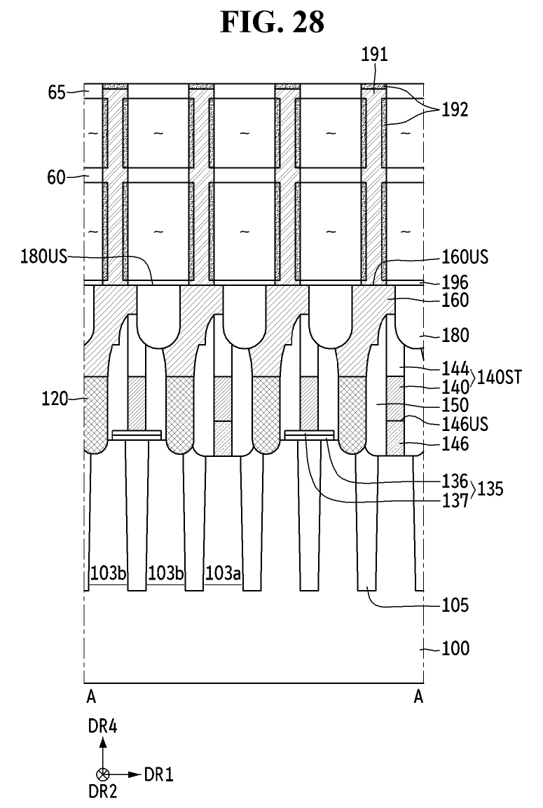

Referring to FIGS. 27 and 28, an opening may be formed in each of the first supporter film 60L and the second supporter film 65L to form each of the first supporter pattern 60 and the second supporter pattern 65.

Although not shown, each of the first supporter pattern 60 and the second supporter pattern 65 may include a through hole. The first mold layer 70 and the second mold layer 75 may be removed using the through hole of the first supporter pattern 60 and the through hole of the second supporter pattern 65.

More specifically, the second supporter pattern 65 may be formed by forming the through hole in the second supporter film 65L. The through hole of the second supporter pattern 65 may expose the second mold layer 75. The second mold layer 75 may be removed using the through hole of the second supporter pattern 65. Subsequently, the through hole may be formed in the first supporter film 60L, and thus the first supporter pattern 60 may be formed. The through hole of the first supporter pattern 60 may be formed at a position corresponding to or overlapping the through hole of the second supporter pattern 65. The through hole of the first supporter pattern 60 may expose the first mold layer 70. The first mold layer 70 may be removed using the through hole of the first supporter pattern 60.

After the first mold layer 70 and the second mold layer 75 are removed, an exposed portion of the first lower electrode 191 may be oxidized. As a result, the first lower inserted electrode film 192 may be formed on the first lower electrode 191.

Referring to FIGS. 28 and 29, after the first lower inserted electrode film 192 is formed, the first lower interfacial electrode film 193 may be formed.

The first capacitor dielectric film 194 may be formed on the first lower interfacial electrode film 193.

Next, referring to FIG. 6, the first upper electrode 195 may be formed on the first capacitor dielectric film 194.

In some embodiments, a method for manufacturing a semiconductor device comprises forming a pre-lower electrode including a first metal element (M1), oxidizing at least a portion of the pre-lower electrode to form a lower electrode and a lower inserted electrode film, the lower inserted electrode film including an oxide of the pre-lower electrode, forming on the lower inserted electrode film a lower interfacial electrode film including a second metal element (M2) different from the first metal element and an oxide of the second metal element, and forming on the lower interfacial electrode film a capacitor dielectric film including a third metal element (M3) different from the second metal element and an oxide of the third metal element.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A semiconductor device comprising:
an upper electrode;
a lower electrode including a first metal element;
a lower inserted electrode film disposed between the upper electrode and the lower electrode, wherein the lower inserted electrode film has a rutile structure, and includes an oxide of the lower electrode;
a lower interfacial electrode film disposed between the lower inserted electrode film and the upper electrode, wherein the lower interfacial electrode film has a rutile structure, and includes a second metal element different from the first metal element and an oxide of the second metal element; and
a capacitor dielectric film disposed between the lower interfacial electrode film and the upper electrode, wherein the capacitor dielectric film has a tetragonal crystal system, and includes a third metal element different from the second metal element and an oxide of the third metal element.

2. The semiconductor device of claim 1, wherein a preferred growth crystal plane of the capacitor dielectric film on the lower electrode is a (110) plane.

3. The semiconductor device of claim 1, wherein the capacitor dielectric film has a rutile structure.

4. The semiconductor device of claim 1, wherein the first metal element includes one of cobalt (Co), copper (Cu), molybdenum (Mo), niobium (Nb), tantalum (Ta), titanium (Ti), or vanadium (V).

5. The semiconductor device of claim 1, wherein the second metal element includes one of cobalt (Co), molybdenum (Mo), niobium (Nb), tin (Sn), tantalum (Ta), titanium (Ti), or vanadium (V).

6. The semiconductor device of claim 5, wherein the lower interfacial electrode film further includes a dopant element different from the second metal element,
wherein the dopant element includes at least one of niobium (Nb), tin (Sn), or tantalum (Ta).

7. The semiconductor device of claim 1, wherein the capacitor dielectric film further includes a dopant element different from the third metal element,
wherein the dopant element of the capacitor dielectric film includes at least one of aluminum (Al), barium (Ba), beryllium (Be), germanium (Ge), magnesium (Mg), niobium (Nb), silicon (Si), tantalum (Ta), or yttrium (Y).

8. The semiconductor device of claim 1, wherein a thickness of the lower inserted electrode film is greater than or equal to a thickness of the lower interfacial electrode film.

9. A semiconductor device comprising:
a landing pad disposed on a substrate;
a lower electrode connected to the landing pad, and extending in one direction, wherein the lower electrode includes a first metal element;
a supporter pattern contacting a portion of the lower electrode and including a first surface and a second surface opposite to each other in the one direction, wherein a sidewall of the supporter pattern connects the first surface of the supporter pattern and the second surface of the supporter pattern to each other, and contacts the lower electrode;
a lower inserted electrode film contacting the lower electrode and including an oxide of the lower electrode;
a lower interfacial electrode film disposed on the lower inserted electrode film and the supporter pattern and contacting the lower inserted electrode film and the supporter pattern, wherein the lower interfacial electrode film extends along the first surface of the supporter pattern and the second surface of the supporter pattern, and includes a second metal element and an oxide of the second metal element;
a capacitor dielectric film disposed on the lower interfacial electrode film and contacting the lower interfacial electrode film, wherein the capacitor dielectric film extends along the first surface of the supporter pattern and the second surface of the supporter pattern, and includes a third metal element and an oxide of the third metal element; and
an upper electrode disposed on the capacitor dielectric film.

10. The semiconductor device of claim 9, wherein the lower inserted electrode film is not disposed on the first surface of the supporter pattern and the second surface of the supporter pattern.

11. The semiconductor device of claim 9, wherein each of the lower inserted electrode film and the lower interfacial electrode film has a rutile structure,
wherein the capacitor dielectric film has a tetragonal crystal system.

12. The semiconductor device of claim 9, wherein a preferred growth crystal plane of the capacitor dielectric film on the lower electrode is a (110) plane.

13. The semiconductor device of claim 9, wherein the first metal element includes one of cobalt (Co), copper (Cu), molybdenum (Mo), niobium (Nb), tantalum (Ta), titanium (Ti), or vanadium (V).

14. The semiconductor device of claim 9, wherein the second metal element includes one of cobalt (Co), molybdenum (Mo), niobium (Nb), tin (Sn), tantalum (Ta), titanium (Ti), or vanadium (V).

15. The semiconductor device of claim 14, wherein the lower interfacial electrode film further includes a dopant element different from the second metal element,
wherein the dopant element includes at least one of niobium (Nb), tin (Sn), or tantalum (Ta).

16. The semiconductor device of claim 15, wherein a content of the dopant element in the lower interfacial electrode film is 5 at.% (atomic percent) or lower.

17. The semiconductor device of claim 9, wherein the first metal element is different from the second metal element,
wherein the third metal element is different from the second metal element.

18. A semiconductor device comprising:
an upper electrode;
a lower electrode including a first metal element or a nitride of the first metal element;
a lower inserted electrode film contacting the lower electrode and disposed between the upper electrode and the lower electrode, wherein the lower inserted electrode film includes an oxide of the lower electrode;
a lower interfacial electrode film contacting the lower inserted electrode film and disposed between the lower inserted electrode film and the upper electrode, wherein the lower interfacial electrode film has a rutile structure, and includes a second metal element different from the first metal element and an oxide of the second metal element; and
a capacitor dielectric film contacting the lower interfacial electrode film and disposed between the lower interfacial electrode film and the upper electrode, wherein the capacitor dielectric film has a tetragonal crystal system, and includes a third metal element different from the second metal element and an oxide of the third metal element,
wherein a preferred growth crystal plane of the capacitor dielectric film on the lower electrode is a (110) plane.

19. The semiconductor device of claim 18, wherein the lower inserted electrode film has a rutile structure.

20. The semiconductor device of claim 18, wherein the first metal element includes one of cobalt (Co), copper (Cu), molybdenum (Mo), niobium (Nb), tantalum (Ta), titanium (Ti), or vanadium (V),
wherein the second metal element includes one of cobalt (Co), molybdenum (Mo), niobium (Nb), tin (Sn), tantalum (Ta), titanium (Ti), or vanadium (V).
